(19) United States
(12) Patent Application Publication
(10) Pub. No.: US 2017/0098716 A1
(43) Pub. Date: Apr. 6, 2017

(54) TWO-DIMENSIONAL HETEROJUNCTION INTERLAYER TUNNELING FIELD EFFECT TRANSISTORS

(71) Applicant: University of Notre Dame du Lac, Notre Dame, IN (US)

(72) Inventors: Mingda Li, Notre Dame, IN (US); David Esseni, Udine (IT); Gregory Snider, Notre Dame, IN (US); Debdeep Jena, Notre Dame, IN (US); Huili Grace Xing, Notre Dame, IN (US)

(21) Appl. No.: 14/629,222

(22) Filed: Feb. 23, 2015

Related U.S. Application Data
(60) Provisional application No. 62/118,980, filed on Feb. 20, 2015.

(51) Int. Cl. H01L 29/786; H01L 29/18; H01L 29/15

(52) U.S. Cl. CPC H01L 29/78648; H01L 29/151; H01L 29/18

(57) ABSTRACT

A two-dimensional (2D) heterojunction interlayer tunneling field effect transistor (Thin-TFET) allows for particle tunneling in a vertical stack comprising monolayers of two-dimensional semiconductors separated by an interlayer. In some examples, the two 2D materials may be misaligned so as to influence the magnitude of the tunneling current, but have a modest impact on gate voltage dependence. The Thin-TFET can achieve very steep subthreshold swing, whose lower limit is ultimately set by the band tails in the energy gaps of the 2D materials produced by energy broadening. These qualities in turn make the Thin-TFET an ideal low voltage, low energy solid state electronic switch.

### CROSS REFERENCE TO RELATED APPLICATION

This application is a non-provisional application claiming priority from U.S. Provisional Application Ser. No. 62/118,980, filed Feb. 20, 2015, entitled “Two-Dimensional Heterojunction Interlayer Tunneling Field Effect Transistors” and incorporated herein by reference in its entirety.

### GOVERNMENT LICENSE RIGHTS

This invention was made with government support under Contract FA9550-12-1-0257 awarded by the Air Force Office of Scientific Research. The government has certain rights in the invention.

### FIELD OF THE DISCLOSURE

The present description relates generally to particle tunneling and field effect transistors and, more particularly, to two-dimensional heterojunction interlayer tunneling field effect transistors.

### BACKGROUND OF RELATED ART

Electronic integrated circuits may be considered the hardware backbone of today's information society. However, power dissipation of such circuits has recently become a considerable challenge. Rates of power consumption in these integrated circuits can affect, for example, the useful lifespan of portable equipment, the sustainability of the ever-increasing number of large data centers, the feasibility of energy-autonomous systems in terms of ambience intelligence, and the feasibility of sensor networks associated with implants and other medical devices, among others. While the scaling of a supply voltage (V_{DD}) is recognized as one of the most effective measures for reducing switching power in digital circuits, the performance loss and increased device-to-device variability are typically seen as serious hindrances to scaling V_{DD} down to 0.5 volts (V) or less.

As the physical limitations of miniaturization appear to approach for complementary metal-oxide-semiconductor (CMOS) technology, the search for alternative devices to extend computer performance has accelerated. In general, any new technology should be energy efficient, dense, and enable more device function per unit space and time. There have been many device proposals, often involving new state variables and communication frameworks. Moreover, it is known in the art that the voltage scalability of very-large-scale integration (VLSI) systems may be significantly improved by resorting to innovations in transistor technology and, in this regard, the International Technology Roadmap for Semiconductors (ITRS) has singled out tunnel field effect transistors (“TFETs” or “tunnel FETs”) as the most promising transistors to reduce sub-threshold swing (SS) below the 60 mV/dec limit of metal-oxide-semiconductor field-effect transistors (MOSFETs) at room temperature and, thus, to enable further V_{DD} scaling. Several device architectures and materials are being investigated to develop tunnel FETs offering both an attractive on-current and a small SS, including group III-group V based transistors, possibly employing staggered or broken bandgap heterojunctions, or strain engineering. Even if encouraging experimental results have been reported for the on-current in group III-V tunnel FETs, achieving a sub-60 mV/dec SS remains a major challenge in these devices, likely due to the detrimental effects of interface states. Therefore, as of now, the investigation of new material systems and innovative device architectures for high performance tunnel FETs is as timely as ever in both the applied physics and the electron device community.

### BRIEF DESCRIPTION OF THE DRAWINGS

FIG. 1 is a schematic diagram of an example 2D heterojunction interlayer tunneling field effect transistor (Thin-TFET).

FIG. 2 is a circuit diagram of an example capacitance model that corresponds to the example Thin-TFET of FIG. 1.

FIG. 3 is an example band diagram that corresponds to the example Thin-TFET of FIG. 1.

FIG. 4 is an example partial band diagram based on the allowed energies associated with WSe₂ and SnSE₂ 2D materials.

FIG. 5 shows a band alignment diagram between top and bottom 2D layers of an example Thin-TFET corresponding to an OFF state.

FIG. 6 shows a band alignment diagram between top and bottom 2D layers of an example Thin-TFET corresponding to an ON state.

FIG. 7 is a diagram of an example rotational misalignment between the top and bottom 2D layers of an example Thin-TFET.

FIG. 8 shows an electron band structure for an example hexagonal monolayer comprised of MoS₂.

FIG. 9 shows an electron band structure for an example hexagonal monolayer comprised of WTe₂.

FIG. 10 is a chart plotting band alignment versus a top gate voltage for top and bottom 2D layers of an example Thin-TFET.

FIG. 11 is a chart plotting tunnel current density versus a top gate voltage of an example Thin-TFET for various correlation lengths.

FIG. 12 is a chart plotting current density versus top gate voltage in an example Thin-TFET based on various interlayer thicknesses.

FIG. 13 is a chart plotting current density versus top gate voltage in an example Thin-TFET based on various values of energy broadening.

FIG. 14 is a chart plotting current density versus top gate voltage in an example Thin-TFET for various values of a drain-source voltage, where no resistance is applied.

FIG. 15 is a chart plotting current density versus drain-source voltage in an example Thin-TFET for various top gate voltages, where no resistance is applied.

FIG. 16 is a chart plotting current density versus top gate voltage in an example Thin-TFET for various drain-source voltages, where at least some resistance is applied.

FIG. 17 is a chart plotting current density versus drain-source voltage in an example Thin-TFET for various top gate voltages, where at least some resistance is applied.

FIG. 18 is a chart plotting capacitance density as taken across terminals G-S and G-D of the example capacitance model of FIG. 2 versus top gate voltage for various drain-source voltages, where no resistance is applied.

FIG. 19 is a chart plotting capacitance density as taken across terminals G-S and G-D of the example capacitance model of FIG. 2 versus drain-source voltage for various top gate voltages, where no resistance is applied.

FIG. 20 is a schematic diagram of an example Thin-TFET in which components of the example Thin-TFET are vertically aligned.

FIG. 21 is a schematic diagram of an example Thin-TFET in which components of the example Thin-TFET are vertically misaligned.

FIG. 22 is a schematic diagram of an example Thin-TFET in which top and bottom 2D layers of the example Thin-TFET are in line with one another.

FIG. 23 is a schematic diagram of an example Thin-TFET in which top and bottom 2D layers of the example Thin-TFET are crisscrossed with respect to one another.

FIG. 24 is a schematic diagram that demonstrates how an example Thin-TFET can be employed to in an inverter.

FIG. 25 is a schematic diagram that demonstrates how an example Thin-TFET can be employed to in a NAND Gate.

### DETAILED DESCRIPTION

The following description of example methods and apparatus is not intended to limit the scope of the description to the precise form or forms detailed herein. Instead the following description is intended to be illustrative so that others may follow its teachings.

Monolayers of group-VIB transition metal dichalcogenides (TMDs) according to the formula MX₂—where M=Mo or W, and where X=S, Se, or Te—have recently attracted attention for their electronic and optical properties. As explained below, these materials may be utilized by the 2D crystal layers in the example 2D heterojunction interlayer tunneling field effect transistors (Thin-TFETs) disclosed herein. Monolayers of TMDs have a bandgap that varies from almost zero to 2 eV with a sub-nanometer thickness. As a result, these materials are considered to be approximately two-dimensional (2D) crystals. 2D crystals, in turn, have recently attracted attention primarily due to their scalability, step-like density of states, and absence of broken bonds at interface. 2D crystals can be stacked to form a new class of tunneling transistors based on an interlayer tunneling occurring in the direction normal to the plane of the 2D materials. In fact, tunneling and resonant tunneling devices have recently been proposed, as well as experimentally demonstrated for graphene-based transistors.

Further, the sub-nanometer thickness of TMDs provides excellent electrostatic control in a vertically stacked heterojunction. What's more, the 2D nature of such materials makes them virtually immune to the energy bandgap increase produced by the vertical quantization when conventional 3D semiconductors are thinned to a nanoscale thickness and, thus, immune to the corresponding degradation of the tunneling current density. Still further, the lack of dangling bonds at the surface of TMDs may allow for the fabrication of material stacks with low densities of interface defects, which is another potential advantage of TMD materials for tunnel FET applications.

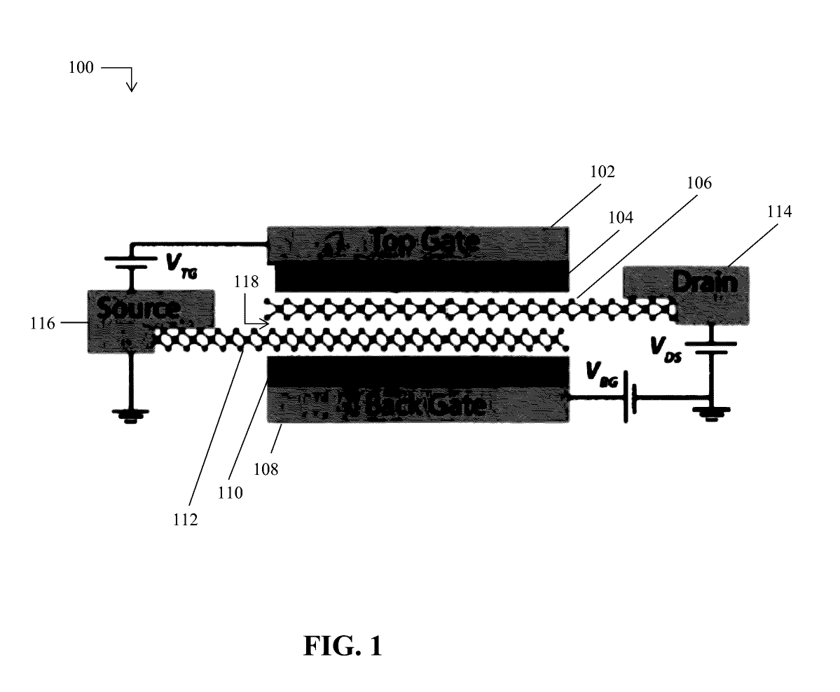

With reference now to the figures, FIG. 1 provides a diagram for an example Thin-TFET 100. In the illustrated instance, the example Thin-TFET 100 includes a top gate 102, a top oxide layer 104, a top 2D layer 106, a back gate 108, a back oxide layer 110, a bottom 2D layer 112, a drain 114, a source 116, and an interlayer 118. By way of schematics, FIG. 1 also shows voltages present at the top gate (V_{TG}), at the back gate (V_{BG}), and across a drain-source terminal of the Thin-TFET 100. In one example, the top oxide layer 104 separates the top gate 102 and the top 2D layer 106. Likewise, in one example, the bottom oxide layer 110 separates the back gate 108 and the bottom 2D layer 112.

Further, in some examples the Thin-TFET 100 includes the interlayer 118, which separates the top and bottom 2D layers 106, 112. The interlayer 118 may, in some cases, take the form of a van der Waals gap that is formed by the lack of chemical bonds between the top and bottom 2D layers 106, 112. Of course, the Thin-TFET 100 is not in any way limited to only those examples in which not a single chemical bond is present between the top and bottom 2D layers 106, 112. As those having ordinary skill in the art will understand, in some examples at least some chemical bonds may be present between the top and bottom 2D layers 106, 112 of the Thin-TFET 100. However, in some instances, material selection of the top and bottom 2D layers 106, 112 is important so as to prevent, or at least minimize, such chemical bonds at the interlayer 118. The example top and bottom 2D layers 106, 112 may be atomically-thick monolayer 2D crystals whose surfaces are free, or at least substantially free, from dangling bonds. Hence, even though FIG. 1 depicts the top and bottom 2D layers 106, 112 as having heights that are comparable to the other components, this is merely for purposes of illustration. Moreover, by way of example, the top 2D layer 106 may comprise SnSe₂, and the bottom 2D layer 112 may comprise WSe₂. Put another way, the top and bottom 2D layers 106, 112 may be semiconductors with sizable energy bandgaps, such as transition metal dichalcogenide (TMD) semiconductors, for example. In some examples, though, the top and bottom 2D layers 106, 112 are devoid of a combination of a p+ crystal and an n+ crystal. Further, one example way in which the top 2D layer 106 can be stacked on top of the bottom 2D layer is via a dry transfer technique or chemical deposition/epitaxy (e.g., MBE, CVD).

Furthermore, it should also be understood that references to “top” and “back”/“bottom” herein may in some examples be interchangeable with references to “first” and “second,” respectively and do not necessarily indicate a required orientation of the Thin-TFET 100, but rather are used merely to assist in understanding the structure of the device. Still further, while the top gate 102, the top oxide layer 104, the top 2D layer 106, the interlayer 118, the bottom 2D layer 112, the back oxide layer 110, and the back gate 108 are aligned in a vertically stack (or “configuration”) in FIG. 1, those having ordinary skill in the art will also appreciate that in some cases the vertical stack of components need not necessarily be aligned in such precise fashion. Yet further, in some examples, the example source 116 is coupled to the example bottom 2D layer 112, and the example drain 114 is coupled to the example top 2D layer 106.

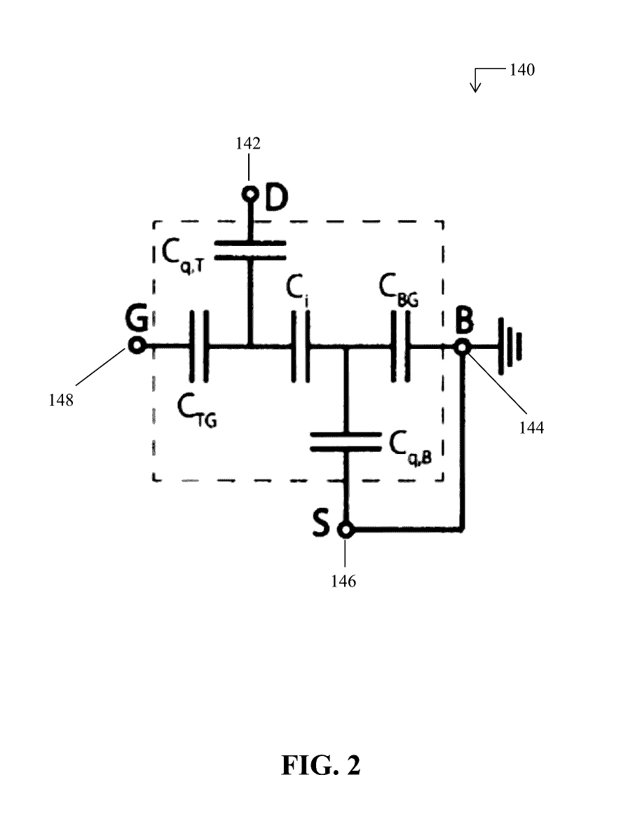

FIG. 2 illustrates a capacitance model 140 that corresponds to the example Thin-TFET 100 of FIG. 1. The capacitance model 140 of FIG. 2 includes terminals 142 (D), 144 (B), 146 (S), and 148 (G) representing, respectively, the drain 114, the back gate 108, the source 116, and the top gate 102. The capacitance model 140 further includes schematic capacitors corresponding to a top gate oxide capacitance C_{TG}, a van der Waals gap capacitance Cᵢ, a bottom gate oxide capacitance C_{BG}, a top 2D layer quantum capacitance C_{q,T}, and a bottom 2D layer quantum capacitance C_{q,B}. Performance of the example Thin-TFET is discussed further below with respect to the capacitance model 140.

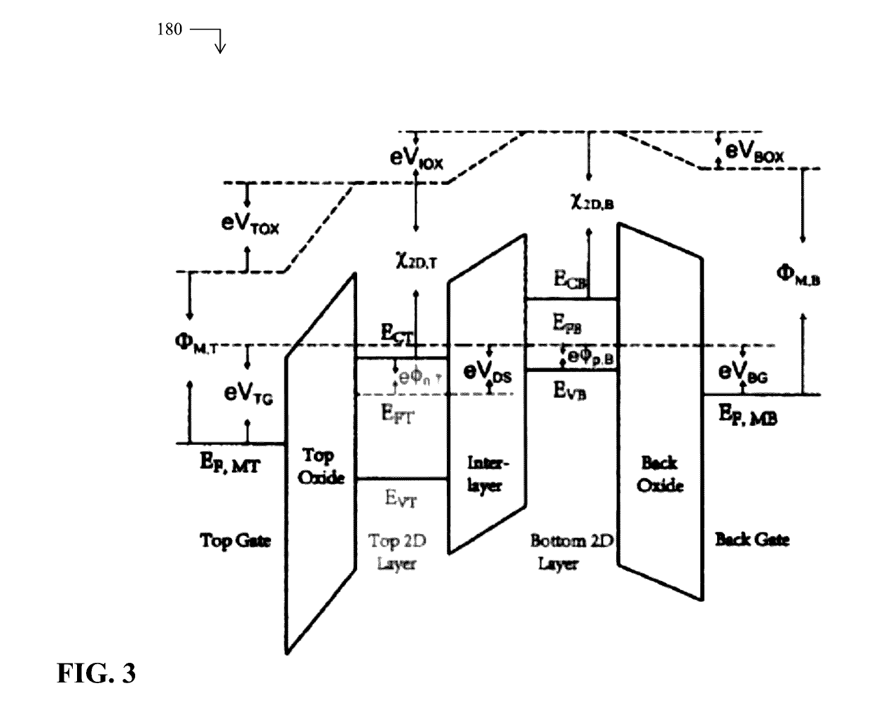

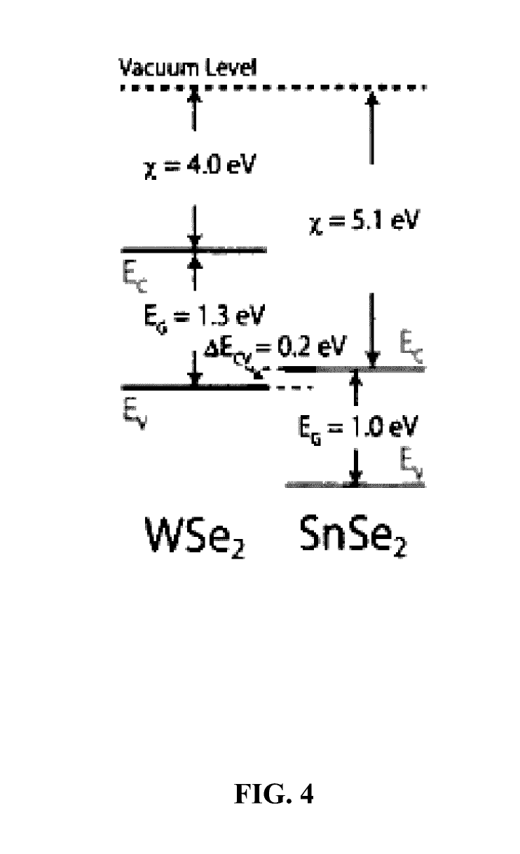

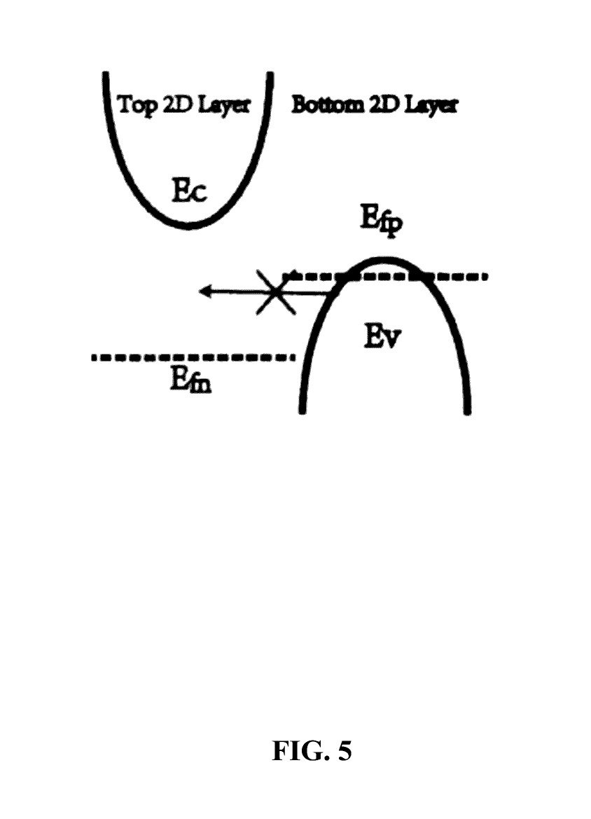

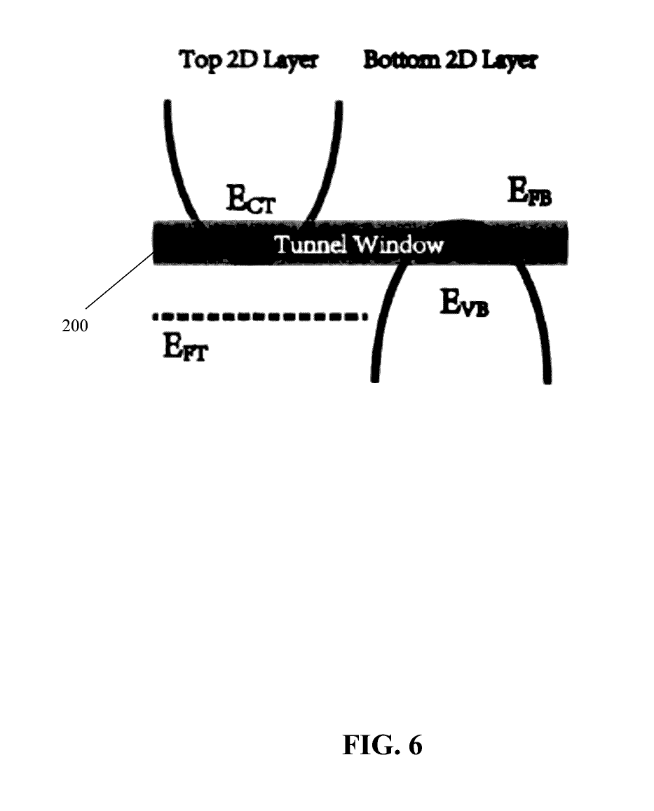

With reference now to FIG. 3, a band diagram 180 corresponding to the example Thin-TFET 100 of FIG. 1 is shown. In this example, work functions are identified as Φ_{T} and Φ_{B}; Fermi levels of the top and back gates 102, 108 are identified as E_{F,MT} and E_{F,MB}, respectively; electron affinities are identified as χ_{2D,T} and χ_{2D,B}; conduction band edges are identified as E_{CT} and E_{CB}; and valence band edges of the top and bottom 2D layers 106, 112 are identified as E_{VT} and E_{VB}, respectively. Potential drops across the top oxide layer 104, the interlayer 118, and the back oxide layer 110 are identified, respectively, as V_{TOX}, V_{IOX}, and V_{BOX}. Thus, when the conduction band edge E_{CT} of the top 2D layer 106 is higher than the valence band edge E_{VB} of the bottom 2D layer 112, there are no states in the top 2D layer 106 into which the electrons of the bottom 2D layer 112 can tunnel. This scenario corresponds to an OFF state of the example Thin-TFET 100, as represented in FIGS. 4-5. In FIG. 4, though, actual numbers have been substituted in that correspond to the allowed energies of WSe₂ and SnSe₂, based on effective masses for holes being 0.4 m₀ and for electrons being 0.3 m₀ for both WSe₂ and SnSe₂. In many examples, the materials comprising the top 2D layer 106 are different from the materials comprising the bottom 2D layer 112. Conversely, when the conduction band edge E_{CT} is pulled below the valence band edge E_{VB}, as shown in FIG. 6, a tunneling window 200 is formed. Consequently, interlayer tunneling can occur from the bottom 2D layer 112 to the top 2D layer 106 when a voltage is applied at at least one of the top and bottom gates 102, 108. The crossing and uncrossing of the top layer conduction band E_{CT} and the bottom layer valence band E_{VB} are governed by the voltages V_{TG} and V_{BG} applied at the top and back gates 102, 108, respectively. Also, it should be understood that the flow of electrons is generally perpendicular to planes in which the top and bottom 2D layers 106, 112 reside. Such tunneling may be said to be “out-of-plane” tunneling.

To determine the band alignment in a vertical direction of the example Thin-TFET 100 in FIG. 1, Gauss Law linking a sheet charge in the top and bottom 2D layers 106, 112 to electric fields in the top and back oxide layers 104, 110 leads to

C_{TOX}V_{TOX}−C_{IOX}V_{IOX}=e(p_{T}−n_{T}+N_{D}),

C_{BOX}V_{BOX}−C_{IOX}V_{IOX}=e(p_{B}−n_{B}+N_{A}), (1)

where C_{TOX}, C_{IOX}, and C_{BOX} are the capacitances per unit area of, respectively, the top oxide layer 104, the interlayer 118, and the back oxide layer 110 and where V_{TOX}, V_{IOX}, and V_{BOX} are the potential drops across, respectively, the top oxide layer 104, the interlayer 118, and the back oxide layer 110. In one example, the potential drop across the top and back oxide layers 104, 110 can be written in terms of the external voltages V_{TG}, V_{BG}, V_{DS}, and in terms of the energy eΦ_{n.T}=E_{CT}−E_{FT} and eΦ_{p.T}=E_{FB}−E_{VB} defined in FIG. 3 as

eV_{TOX}=eV_{TG}+eφ_{n.T}−eV_{DS}+χ_{2D.T}−Φ_{M.T.},

eV_{BOX}=eV_{BG}−eφ_{p.B}+E_{GB}+χ_{2D.B}+Φ_{M.B.},

eV_{IOX}=eV_{DS}+eφ_{p.B}−eφ_{n.T}+E_{GB}+χ_{2D.B}−χ_{2D.T} (2)

where E_{FT} and E_{FB} are Fermi levels of majority carriers in the top and bottom 2D layers 106, 112. In some examples, n_{T}, p_{T} are the electron and hole concentrations in the top 2D layer 106; n_{B}, p_{B} are the concentrations in the bottom 2D layer 112; x_{2D,T}, x_{2D,B} are the electron affinities of the top and bottom 2D layers 106, 112; Φ_{T} and Φ_{B} are the work functions of the top and back gates 102, 108; and E_{GB} is the energy gap in the bottom 2D layer 112. Equation (2) is based on an assumption that majority carriers of the top and bottom 2D layers 106, 112 are at thermodynamic equilibrium with their Fermi levels, with the split of the Fermi levels set by the external voltages (i.e., E_{FB}−E_{FT}=eV_{DS}), and the electrostatic potential essentially constant in the top and bottom 2D layers 106, 112.

Because a parabolic effective mass approximation for the energy dispersion of the 2D materials is employed herein, the carrier densities can be expressed as an analytic function of eΦ_{n.T} and eΦ_{p.B}

$$n ( p ) = \frac{{g}_{v} {m}_{c ( {m}_{v} )} {k}_{B} T}{m {ℏ}^{2}} ln [ exp ( - \frac{q {φ}_{n , T} ( {φ}_{p , B} )}{{k}_{B} T} ) + 1 ] , \qquad ( 3 )$$

where gᵥ is the valley degeneracy.

In some examples it is possible to determine the tunneling current of the example Thin-TFET 100 based on the transfer-Hamiltonian method used in the context of resonant tunneling in graphene transistors. The single particle elastic tunneling current may be represented as

$$1 = {g}_{v \frac{4 π e}{ℏ}} {\sum }_{{k}_{T} , {k}_{B}} {\vert M ( {k}_{T} , {k}_{B} ) \vert}^{2} δ ( {E}_{B} ( {k}_{B} ) - {E}_{T} ( {k}_{T} ) ) ( {f}_{B} - {f}_{T} ) \qquad ( 4 )$$

where e is the elementary charge; k_{B} and k_{T} are wave-vectors, respectively, in the bottom and top 2D layers 112, 106; where E_{B}(k_{B}) and E_{T}(k_{T}) denote corresponding energies of the bottom and top 2D layers 112, 106; where f_{B} and f_{T} are Fermi occupation functions in the bottom and top 2D layers 112, 106 (i.e., depending respectively on E_{FB} and E_{FT} with respect to FIG. 3); and where gᵥ is valley degeneracy. Matrix element M(k_{T}, k_{B}) represents the transfer of electrons between the top and bottom 2D layers 106, 112 and is given by

M(k_{T},k_{B},)=∫_{A}dr∫dz_{T,k}_{_{T}}^{†}(r,z)U_{sc}(r,z)ψ_{B,k}_{_{B}}(r,z), (5)

where Ψ_{B,k}_{_{B}} (Ψ_{T,k}_{_{T}}) is an electron wave-function of the bottom (top) 2D layer 112; where Ψ_{T,k}_{_{T}} is an electron wave-function of the top 2D layer 106; and where U_{sc}(r, z) is a perturbation potential in the interlayer 118 region. It should be understood that Equation (5) accounts for the fact that several physical mechanisms occurring in the interlayer 118 region can in some cases result in a relaxed conservation of the in plane wave-vector k in the tunneling process.

In some examples, to determine M (k_{T}, k_{B}), the electron wave-function may be written in Bloch function form as

$${ψ}_{k ( r , z )} = \frac{1}{\sqrt{{N}_{c}}} {e}^{i k \cdot r {u}_{k ( r , z )}} , \qquad ( 6 )$$

where uₖ (r, z) is a periodic function of r and where N_{c} is the number of unit cells in an overlapping area A of the top and bottom 2D layers 106, 112. Equation (6) assumes the following normalization condition:

∫_{Ω}_{_{C}}dρ∫_{Z}dz|u_{k(ρ,z)}|²=1, (7)

where ρ is the in-plane abscissa in the unit cell area Ω_{C} and the overlapping area A=N_{C}Ω_{C}.

The wave-function Ψₖ (r, z) presumably decays exponentially in the interlayer 118 with a decay constant κ. Such a z dependence can be absorbed in uₖ(r, z) based on various derivations as will be understood by those having ordinary skill in the art. Moreover, it should be understood that absorbing the exponential decay in uₖ (r, z) accounts for the fact that in the interlayer 118 the r dependence of the wave-function changes with z in some instances. In fact, as disclosed above, while uₖ (r, z) is localized around basis atoms in the top and bottom 2D layers 106, 112, these functions spread out while they decay in the interlayer 118 so that the r dependence becomes weaker when moving farther from the 2D layers.

To determine M (k_{T}, k_{B}), a scattering potential in the interlayer 118 may be separable in the form

U_{sc}(r,z)=V_{B}(z)F_{L}(r), (8)

where F_{L}(r) is the in-plane fluctuation of the scattering potential, which is essentially responsible for the relaxation of momentum conservation in the tunneling process. By substituting Equations (6) and (8) into Equation (5) and writing r=rⱼ+ρ, where rⱼ is a direct lattice vector and ρ is the in-plane position inside each unit cell, the following is obtained:

$$M ( {k}_{T} , {k}_{B} ) = \frac{1}{{N}_{c}} {\sum }_{j = 1}^{{N}_{c}} {e}^{i ( {k}_{B} - {k}_{r} ) \cdot {r}_{j}} {\int }_{{Ω}_{c}} d ρ \int d z {e}^{i ( {k}_{B} - {k}_{r} ) \cdot ρ} \times {u}_{T , {k}_{T}}^{†} ( {r}_{j + ρ , z} ) {F}_{L} ( {r}_{j} + ρ ) {V}_{B} ( z ) {u}_{B , {k}_{B}} ( {r}_{j} + ρ , z ) \qquad ( 9 )$$

In some cases, F_{L}(r) corresponds to relatively long range fluctuations, so that F_{L}(r) is relatively constant inside a unit cell and that, furthermore, the top and bottom 2D layers 106, 112 have the same lattice constant. Hence the Bloch functions u_{T.k}_{_{T}} and u_{B.k}_{_{B}} may have the same periodicity in the r plane. In addition, the conduction band minimum in the top 2D layer 106 and the valence band maximum in the bottom 2D layer 112 may be considered to be at the same point of the 2D Brillouin zone, so that q=k_{B}−k_{T} is small compared to the size of the Brillouin zone and e^{lq·ρ} equals approximately 1.0 inside a unit cell. In turn, Equation 9 may be rewritten as

$$M ( {k}_{T} , {k}_{B} ) ≃ \frac{1}{{N}_{c}} {\sum }_{j = 1}^{{N}_{c}} {e}^{{i}_{q} \cdot {r}_{j}} {F}_{L} ( {r}_{j} ) {\int }_{{Ω}_{c}} d ρ \int d z {u}_{T , {k}_{T}}^{†} ( ρ , z ) \times {V}_{B} ( z ) {u}_{B , {k}_{B}} ( ρ , z ) \qquad ( 10 )$$

where the integral in the unit cell has been written for rj=0 because it is independent of the unit cell.

In keeping with k_{B} and k_{T} being small compared to the size of the Brillouin zone, in Equation 10 the k_{B} (k_{T}) dependence of u_{B,k}_{_{B}} (u_{T,k}_{_{T}}) can be neglected such that u_{T.k}_{_{T}} (ρ, z)≈u_{0T} (ρ, z) and u_{B.k}_{_{B}} (ρ, z)≈u_{oB} (ρ, z), where u_{0T} (ρ, z) and u_{0B} (ρ, z) are periodic parts of the Bloch function at the band edges, which is a simplification typically employed in the effective mass approximation approach. Because u_{0B} and u_{0T} retain the exponential decay of the wave-functions in the interlayer 118 with a decay constant κ, it will be understood that

∫_{Ω}_{_{C}}dρ∫dzu_{0T}^{†}(ρ,z)V_{B(z)}u_{0B}(ρ,z)≅M_{BO}e^{-κT}^{_{IL}} (11)

where T_{IL} represents a thickness of the interlayer 118 and M_{B0} is a k independent matrix element that remains a prefactor in the final expression for the tunneling current. Because F_{L}(r) is a slowly varying function over a unit cell, the sum over the unit cells in Equation (10) can be rewritten as a normalized integral over the tunneling area A

$$\frac{1}{{Ω}_{c} {N}_{c}} {\sum }_{j = 1}^{{N}_{c}} {Ω}_{c} {e}^{{i}_{q} \cdot {r}_{j}} {F}_{L} ( {r}_{j} ) ≃ \frac{1}{A} {\int }_{A} {e}^{{i}_{q} \cdot r} {F}_{L} ( r ) d r . \qquad ( 12 )$$

Still further, by introducing Equations (11) and (12) into Equation (10), the squared matrix element can be represented as

$${\vert M ( {k}_{T} , {k}_{B} ) \vert}^{2} ≃ \frac{{\vert {M}_{B 0} \vert}^{2} {S}_{F} ( q )}{A} {e}^{- 2 κ {T}_{IL}} \qquad ( 13 )$$

where q=k_{B}−k_{T} and where S_{F}(q) is a power spectrum of the random fluctuation described by F_{L}(r), which is defined as

$${S}_{F ( q )} = \frac{1}{A} {\vert {\int }_{A} {e}^{{i}_{q} \cdot r} {F}_{L} ( r ) d r \vert}^{2} \qquad ( 14 )$$

Yet further, by substituting Equation (13) into Equation (4) and then converting the sums over k_{B} and k_{T} to integrals, the following is obtained:

$$I = \frac{{g}_{v} e {\vert {M}_{B 0} \vert}^{2} A}{4 {π}^{3} ℏ} {e}^{- 2 κ {T}_{IL}} {\int }_{{k}_{T}} {\int }_{{k}_{B}} d {k}_{T} d {k}_{B} {S}_{F} ( q ) δ ( {E}_{B} ( {k}_{B} ) - {E}_{T} ( {k}_{T} ) ( {f}_{B} - {f}_{T ) .} \qquad ( 15 )$$

According to Equation (15), current is proportional to the squared matrix element |M_{BO}|² defined in Equation (11) and decreases exponentially with the thickness T_{IL} of the interlayer 118 according to the decay constant κ of the wave-functions. The equations thus far resort to a semi-empirical formulation of the matrix element given by Equation (11), where M_{BO} is left as a parameter to be determined and discussed by comparing to experiments. A multitude of challenges are avoided by doing so. However, those having ordinary skill in the art would recognize how to modify the equations identified above if, for example, one were to derive a quantitative expression for M_{BO}, if one were to specify how the periodic functions u_{0T}(ρ, z) and u_{0B} (ρ, z) spread out when they decay in the barrier region, and if one were to identify what potential energy and/or which Hamiltonian should be used to describe the barrier region itself (e.g., an effective barrier height of the van der Waals gap between two 2D crystals of 1.0 eV). Likewise, it should be understood that even though giant spin-orbit couplings have been reported in 2D TMDs, the effects of spin-orbit interaction in the bandstructure of 2D materials have been omitted from the equations above. Also, if energy separations between spin-up and spin-down bands are large, then the spin degeneracy in current calculations should be one instead of two, which would affect the magnitude, but not dependence on gate bias. Further, the equations above could also be modified to account for different band structures in TMD materials produced by a vertical electrical field. However, such effects are negligible due to the magnitude of the electrical field employed in the top and bottom 2D layers 106, 112 of the example Thin-TFET 100.

Nonetheless, in some examples the decay constant κ in the interlayer 118 may be approximated from the electron affinity difference between the top and bottom 2D layers 106, 112 and the interlayer 118 material. Moreover, according to Equation (15) the constant κ determines the dependence of the current on T_{IL}, and κ in many cases is known according to prior studies (e.g., values of κ reported for an interlayer tunneling current in a graphene-hBN system).

As for the power spectrum S_{F}(q) of the scattering potential, which is represented as

$${S}_{F} ( q ) = \frac{π {L}_{c}^{2}}{{( 1 + {q}^{2} {L}_{c}^{2} \text{/} 2 )}^{3 / 2}} \qquad ( 16 )$$

where q=|q| and where L_{C} is the correlation length, which is assumed to be large compared to the size of a unit cell. In some instances, Equation (16) is consistent with an exponential form of an autocorrelation function of F_{L}(r), and a similar q dependence is employed to reproduce the experimentally observed line-width of the resonance region in graphene interlayer tunneling transistors. Such a functional form is representative, at least in some examples, of phonon assisted tunneling, short-range disorder, charged impurities, or Moiré patterns (e.g., at a graphene-hBN interface). As explained below, the correlation length L_{C} influences the gate voltage dependent current.

According to Equations (4) and (15), the tunneling current through the example Thin-TFET 100 is zero when there is no energy overlap between the conduction band E_{CT} in the top 2D layer 106 and the valence band E_{VB} in the bottom 2D layer 112 (i.e., E_{CT}>E_{VB}). It should be understood that the 2D materials of the top and bottom 2D layers 106, 112 inevitably have phonons, disorder, and host impurities and are affected by the background impurities in the surrounding materials. Hence a finite broadening of energy levels occurs because of the statistical potential fluctuations superimposed to the ideal crystal structure. The energy broadening in 3D semiconductors is known to lead to a tail of the density of states (DoS) in a gap region, which is also observed in optical absorption measurements and denoted the “Urbach tail.” It follows that in some examples the finite energy broadening is a fundamental limit to the abruptness of the turn on characteristic attainable with the example Thin-TFETs.

In some cases, energy broadening in 2D systems stems from interactions with randomly distributed impurities and disorder in the top and bottom 2D layers 106, 112 or in the surrounding materials, by scattering events induced by the interfaces, as well as by other scattering sources. For purposes of simplicity, a detailed description of energy broadening is omitted. Notwithstanding, the density of states ρ₀(E) for a 2D layer with no energy broadening is

$${ρ}_{0} ( E ) = \frac{{g}_{s} {g}_{v}}{4 {π}^{2}} {\int }_{k} d k δ [ E - E ( k ) ]$$

where E(k) denotes the energy relation with no broadening and where gₛ represents spin and where gᵥ represents valley degeneracy. Put another way, in the presence of a randomly fluctuating potential V(r), the DoS can be written as

$$ρ ( E ) = {\int }_{0}^{∞} d v {ρ}_{0} ( v ) {P}_{v} ( E - v ) = \frac{{g}_{s} {g}_{v}}{4 {π}^{2}} {\int }_{k} d k [ {\int }_{0}^{∞} d v δ [ v - E ( k ) ] {P}_{v} ( E - v ) ] = \frac{{g}_{s} {g}_{v}}{4 {π}^{2}} {\int }_{k} d k {P}_{v} [ E - E ( k ) ] \qquad ( 18 )$$

where Pᵥ (v) is the distribution function for V(r), as explained below, and where the p₀(E) definition in Equation (17) is used to go from the first equality to the second equality.

By way of comparison of Equation (18) to Equation (17), it can be seen that the ρ(E) of the example Thin-TFET 100 in the presence of energy broadening is calculated by substituting the Dirac function in Equation (17) with a finite width function Pᵥ(v), which is the distribution function of V(r), and it is thus normalized to one.

To include the effects of energy broadening in the calculations, the tunneling rate is rewritten in Equation (4) as

$$\frac{1}{{τ}_{{k}_{T} , {k}_{B}}} = \frac{2 π}{ℏ} {\vert M ( {k}_{T} , {k}_{B} ) \vert}^{2} δ [ {E}_{T} ( {k}_{T} ) - {E}_{B} ( {k}_{B} ) ] = \frac{2 π}{ℏ} {\vert M ( {k}_{T} , {k}_{B} ) \vert}^{2} {\int }_{- ∞}^{∞} d E δ [ E - {E}_{T} ( {k}_{T} ) ] δ [ E - {E}_{B} ( {k}_{B} ) ] \qquad ( 19 )$$

It will be appreciated that, consistent with Equation (18), energy broadening can be included in the current calculation by substituting δ[E−E(k)] with Pᵥ[E−E(k)]. In turn, the tunneling rate becomes

$$\frac{1}{{τ}_{{k}_{T} , {k}_{B}}} ≃ \frac{2 π}{ℏ} {\vert M ( {k}_{T} , {k}_{B} ) \vert}^{2} {S}_{E} ( {E}_{T} ( {k}_{T} ) - {E}_{B} ( {k}_{B} ) ) \qquad ( 20 )$$

where an energy broadening spectrum S_{E} is defined as

S_{E}(E_{T}(k_{T})−E_{B}(k_{B}))=∫_{-∞}^{∞}dEP_{vT}[E−E_{T}(k_{T})]×P_{vB}[E−E_{B}(k_{B})] (21)

where P_{vT} and P_{vB} are potential distribution functions due to the presence of randomly fluctuating potential V(r) in, respectively, the top and the bottom 2D layers 106, 112.

In view of Equation (20), in terms of the tunneling current, energy broadening was accounted for by using in all calculations the broadening spectrum S_{E}(E_{T}(k_{T})−E_{B}(k_{B})) defined in Equation (21) in place of δ[E_{T}(k_{T})−E_{B}(k_{B})]. More specifically, a Gaussian potential distribution was used for both the top and the bottom 2D layers 106, 112:

$${P}_{v} ( E - {E}_{k 0} ) = \frac{1}{\sqrt{π} σ} {e}^{- {( E - {E}_{k 0} )}^{2} / {σ}^{2}} \qquad ( 22 )$$

which has been derived for energy broadening induced by randomly distributed impurities, in which case σ is expressed in terms of the average impurity concentration.

Further, for the Gaussian spectrum in Equation (22), the overall broadening spectrum S_{E} defined in Equation (21) is calculated analytically and reads

$${S}_{E} ( {E}_{T} ( {k}_{T} ) - {E}_{B} ( {k}_{B} ) ) = \frac{1}{\sqrt{π} ( {σ}_{T}^{2} + {σ}_{B}^{2} )} {e}^{- {( {E}_{T} ( {k}_{T} ) - {E}_{B} ( {k}_{B} ) )}^{2} / {σ}^{2}} \qquad ( 23 )$$

Hence S_{E} also has a Gaussian spectrum, where σ_{T} and σ_{B} are, respectively, broadening energies for the top and bottom 2D layers 106, 112.

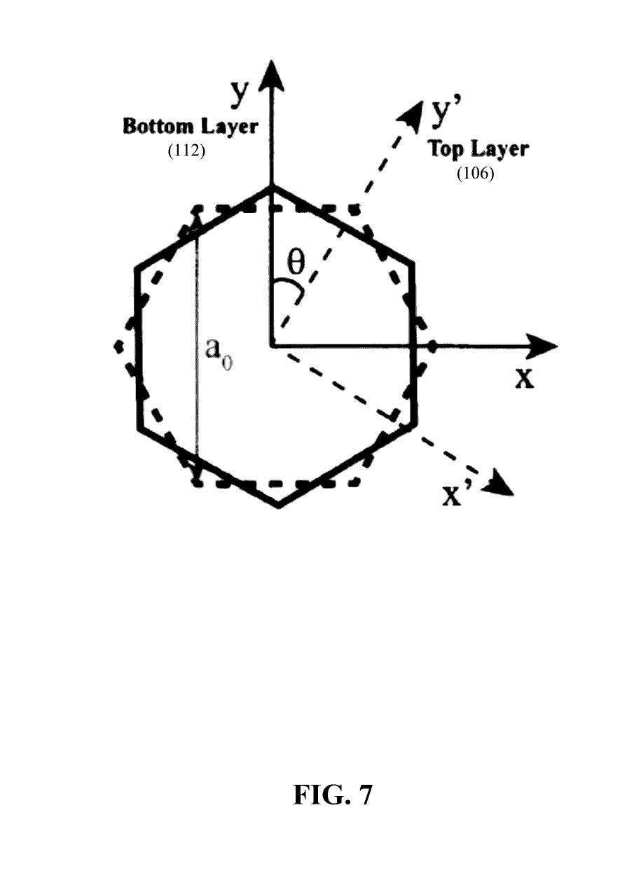

Many of the derivations above assumed a perfect rotational alignment between the lattice structures of the top and bottom 2D layers 106, 112 and that tunneling occurs between equivalent extrema in the Brillouin zone, that is, tunneling from a K to a K extremum (or from K′ to K′ extremum). As shown in FIG. 7, an angle expressing a possible rotational misalignment between the top and bottom 2D layers 106, 112 is denoted θ, where x-y is a reference coordinate for the bottom 2D layer 112 and x′-y′ is a reference coordinate for the top 2D layer 106. However, it is still assumed that the crystal of the top 2D layer 112 has the same lattice constant a₀ as the crystal of the bottom 2D layer 112. A principal coordinate system is taken as the crystal coordinate system in the bottom 2D layer 112, and r′, k′ are denoted as the position and wave vectors in the crystal coordinate system of the top 2D layer 106, where r, k are the vectors in the principal coordinate system. The wave-function in the top 2D layer 106 has the form given in Equation (6) in terms of r′, k′. Hence, to calculate the matrix element in the principal coordinate system, it is said that r′=\hat{R}_{B→T}r, k′=\hat{R}_{B→T}k, where \hat{R}_{B→T} is the rotation matrix from the bottom to the top coordinate system, with \hat{R}_{T→B}=[\hat{R}_{B→T}]^{T} being the matrix going from the top to the bottom coordinate system and M^{T} denoting the transpose of the matrix M. The rotation matrix can be written as

$${\hat{R}}_{T \to B} = ( \begin{matrix}cos θ & - sin θ \\ sin θ & cos θ\end{matrix} ) \qquad ( 24 )$$

in terms of the rotational misalignment angle θ.

To be consistent, u_{T}_{₁}ₖ_{_{T}} (r′, z)≈u_{0T} (r′, z), u_{B}_{₁}ₖ_{_{B}} (r, z)≈u_{0B} (r, z), where u_{0T} (r′, z), u_{0B} (r, z) are the periodic portions of the Bloch function, respectively, at the band edge in the top and bottom 2D layers 106, 112. Further, K_{0T} is denoted as the wave-vector at the conduction band edge in the top 2D layer 106, which is expressed in terms of the top layer coordinate system, and K_{0B} is denoted as the wave-vector at the valence band edge in the bottom layer, which is expressed in terms of the principal coordinate system. Derivations account for the fact that K_{0T} and K_{0B} may be nonequivalent extrema (i.e., K_{0T}≠K_{0B}) in some examples.

By expressing r′ and k′ in the principal coordinate system, the matrix element can be written as

$$M ( {k}_{T} , {k}_{B} ) ≃ \frac{1}{{N}_{C}} {\sum }_{j = 1}^{{N}_{C}} {e}^{i ( q + {Q}_{D} ) \cdot {r}_{j}} {F}_{L} ( {r}_{j} ) \times {\int }_{{Ω}_{C}} d r \int d {zu}_{OT}^{†} \times ( {\hat{R}}_{B \to T} ( {r}_{j} + ρ ) , z ) {V}_{B} ( z ) {u}_{OB} ( {r}_{j} + ρ , z ) \qquad ( 25 )$$

where q=(k_{B}−k_{T}) and the vector

Q_{D}=K_{0B}−\hat{R}_{T→B}K_{0T} (26)

is introduced.

Equation (25) is an extension of Equation (10) and accounts for a possible rotational misalignment between the top and bottom 2D layers 106, 112 and also describes tunneling between nonequivalent extrema. The vector Q_{D} is zero only for tunneling between equivalent extrema (i.e., K_{0B}=K_{0T}) and for a perfect rotational alignment (i.e., θ=0). In a case where all extrema are at the K point and |K_{0B}|=|K_{0T}|=4π/3a₀, then for K_{0B}=K_{OT} the magnitude of Q_{D} is given by Q_{D}=(8π/3a₀)sin(θ/2).

One difference in Equation (25) compared to Equation (10) is that, in the presence of rotational misalignment, the top layer Bloch function u_{0T} (\hat{R}_{B→T}r,z) has a different periodicity in the principal coordinate system from the bottom layer u_{0B} (r, z). As a result, the integral over the unit cells of the bottom 2D layer 112 is not the same in all unit cells, so that the derivations going from Equation (10) to Equation (15) should be rewritten accounting for a matrix element M_{B0j} depending on the unit cell j. Such an M_{B0j} could be included in the calculations by defining a new scattering spectrum that includes not only the inherently random fluctuations of the potential F_{L}(r), but also the cell to cell variations of the matrix element M_{B0j}. A second difference of Equation (25) compared to Equation (10) lies in the presence of Q_{D} in the exponential term multiplying F_{L}(rⱼ).

In the case of tunneling between nonequivalent extrema and with a negligible rotational misalignment (i.e., θ≅0), Equation (26) gives Q_{D}=K_{0B} K_{0T}, and the current can be expressed as in Equation (15), but with the scattering spectrum evaluated at |q+Q_{D}|. Because in this case the magnitude of Q_{D} is comparable to the size of the Brillouin zone, the tunneling between nonequivalent extrema is substantially suppressed if the correlation length L_{c} of the scattering spectrum S_{F}(q) is much larger than the lattice constant, as has been assumed in all derivations. Further, the derivations suggest that rotational misalignment affects the absolute value of the tunneling current, but not to change significantly its dependence on the terminal voltages.

Furthermore, if the vertical stack of the 2D materials is obtained using a dry transfer method, rotational misalignment is nearly inevitable. Tests have shown that, when the stack of 2D materials is obtained by growing the one material on top of the other, the top 2D layer 106 and the bottom 2D layer 112 have a fairly good angular alignment.

An analytical, approximated expression for the tunneling current is useful for a number of reasons, including to gain insight about the main physical and material parameters affecting the current versus voltage characteristic of the example Thin-TFET 100. To derive an analytical current expression, a parabolic energy relation is assumed, which allows for the following expression:

$${E}_{VB} ( {k}_{B} ) = {E}_{VB} - \frac{{ℏ}^{2} {k}_{B}^{2}}{2 {m}_{v}} {E}_{CT} ( {k}_{T} ) = {E}_{CT} + \frac{{ℏ}^{2} {k}_{T}^{2}}{2 {m}_{c}} \qquad ( 27 )$$

where E_{VB} (k_{B}), E_{CT}(k_{T}) are the energy relation, respectively, in the bottom 2D layer valence band and the top 2D layer conduction band and mᵥ and m_{c} are the corresponding effective masses.

It should be understood that energy broadening is neglected here, and Equation (15) is used as a starting point. Consequently, these equations are valid for the ON state of the example Thin-TFET 100 (i.e., E_{CT}<E_{VB}).

Turning to the integral over k_{B} and k_{T} in Equation (15) and introducing polar coordinates k_{B}=(k_{B}, θ_{R}), k_{T}=(k_{T}, θ_{T}) allows for the use of Equation (27) to convert the integrals over k_{B}, k_{T} to integrals over respectively E_{B}, E_{T}, which leads to

$$I ∝ {\int }_{{k}_{T}} {\int }_{{k}_{B}} d {k}_{T} d {k}_{B} {S}_{F} ( q ) δ ( {E}_{B} ( {k}_{B} ) - {E}_{T} ( {k}_{T} ) ) ( {f}_{B} - {f}_{T} ) = \frac{{m}_{c} {m}_{v}}{{ℏ}^{4}} {\int }_{0}^{2 π} d {θ}_{B} {\int }_{0}^{2 π} d {θ}_{T} {\int }_{{E}_{CT}}^{∞} d {E}_{T} {\int }_{- ∞}^{{E}_{VB}} d {E}_{B} {S}_{F} ( q ) \times δ ( {E}_{B} - {E}_{T} ) ( {f}_{B} - {f}_{T} ) \qquad ( 28 )$$

where the spectrum S_{F}(q) is given by Equation (16) and thus depends only on the magnitude q of q=k_{B}−k_{T}. Assuming that E_{CT}<E_{VB}, the Dirac function reduces one of the integrals over the energies and sets E=E_{B}=E_{T}. Furthermore, the magnitude of q=k_{B}−k_{T} depends only on the angle θ=θ_{B}−θ_{T}, so that Equation (28) simplifies to

$$I ∝ \frac{{m}_{c} {m}_{v} ( 2 π )}{{ℏ}^{4}} {\int }_{0}^{2 π} d θ {\int }_{{E}_{CT}}^{{E}_{VB}} d E {S}_{F} ( q ) ( {f}_{B} - {f}_{T} ) \qquad ( 29 )$$

With respect to the ON state (i.e., E_{CT}<E_{VB}) for the example Thin-TFET 100, the zero Kelvin approximation for the Fermi-Dirac occupation functions f_{B}, f_{T} are introduced to further simplify Equation (29) to:

$$I ∝ \frac{{m}_{c} {m}_{v} ( 2 π )}{{ℏ}^{4}} {\int }_{0}^{2 π} d θ {\int }_{{E}_{min}}^{{E}_{max}} d E {S}_{F} ( q ) \qquad ( 30 )$$

where Eₘᵢₙ=max {E_{CT}, E_{FT}}, where Emax=min {E_{VB}, E_{FB}}, and where the tunneling window can be defined by [Emax−Emin].

The evaluation of Equation (30) requires expressing q as a function of the energy E inside the tunneling window and of the angle θ between k_{B} and k_{T}. Because q²=k_{B}²+k_{T}²−2k_{B}k_{T} cos(θ), Equation 27 can be written as follows:

$${q}^{2} = \frac{2 {m}_{v}}{{ℏ}^{2}} ( {E}_{VB} - E ) + \frac{2 {m}_{c}}{{ℏ}^{2}} ( E - {E}_{CT} ) - \frac{4 \sqrt{{m}_{c} {m}_{v}}}{{ℏ}^{2}} \sqrt{( {E}_{VB} - E ) ( E - {E}_{CT} )} cos ( θ ) \qquad ( 31 )$$

where E=E_{R}=E_{T}. By substituting Equation (31) into the spectrum S_{F}(q), the resulting integrals over E and θ in Equation (30) cannot be evaluated analytically. To proceed further, therefore, the maximum value taken by q² is examined. The θ value leading to the largest q² is θ=π, and the resulting q² expression can be further maximized with respect to the energy E varying in the tunneling window. In one example, the energy leading to maximum q² is

$${E}_{M} = \frac{{E}_{CT} + ( {m}_{c} \text{/} {m}_{v} ) {E}_{VB}}{1 + ( {m}_{c} \text{/} {m}_{v} )} \qquad ( 32 )$$

Moreover, the corresponding q_{M}² may be written as follows:

$${q}_{M}^{2} = \frac{2 ( {m}_{c} + {m}_{v} ) ( {E}_{VB} - {E}_{CT} )}{{ℏ}^{2}} \qquad ( 33 )$$

When neither the top nor the bottom 2D layers 106, 112 are degenerately doped, the tunneling window is given by Eₘᵢₙ=E_{CT} and Eₘₐₓ=E_{VB}, in which case the E_{M} defined in Equation (32) belongs to the tunneling window, and the maximum value of q² is given by Equation (33). If either the top or the bottom 2D layer 106, 112 is degenerately doped, the Fermi levels may become the edges of the tunneling window, and the maximum value of q² may be smaller than in Equation (33).

A considerable simplification in the evaluation of Equation (30) is obtained for q_{M}²<<1/L_{c}², in which case Equation (16) returns to S_{F}(q)≈πL_{c}², so that by substituting S_{F}(q) into Equation (29) and then into Equation (15), the expression for the current simplifies to:

$$I ≃ \frac{{eg}_{v} A ( {m}_{c} {m}_{v} )}{{ℏ}^{5}} {\vert {M}_{B 0} \vert}^{2} {e}^{- {2}_{K} {T}_{IL}} {L}_{c}^{2} ( {E}_{max} - {E}_{min} ) \qquad ( 34 )$$

where Eₘᵢₙ=max {E_{CT},E_{FT}} and Eₘₐₓ=min{E_{VB}, E_{FB}} define the tunneling window.

It should be understood that Equation (34) is consistent with a loss of momentum conservation, such that the current is simply proportional to the integral over the tunneling window of the product of the density of states in the top and bottom 2D layers 106, 112. Because the density of states is energy independent for a parabolic effective mass approximation, the current is proportional to the width of the tunneling window. In physical terms, Equation (34) corresponds to a situation where the scattering produces a complete momentum randomization during the tunneling process.

As long as the top 2D layer 106 is not degenerate, Eₘᵢₙ=E_{CT} and the tunneling window widens with the increase of the top gate voltage V_{TG}. Hence, as represented in Equation (34), the current increases linearly with V_{TG}. However, when the tunneling window increases to such an extent that q_{M}² becomes comparable to or larger than 1/L_{c}², then part of the q values in the integration of Equation (30) may belong to the tail of the spectrum S_{F}(q) defined in Equation (16). As a result, their contributions to the current become progressively diminished. In terms of the example Thin-TFET 100, while the tunneling window grows, the magnitude of the wave-vectors in the top and bottom 2D layers 106, 112 also increases, and, consequently, the scattering can no longer provide momentum randomization for all possible wave-vectors involved in the tunneling process. In such circumstances, the current first increases sub-linearly with V_{TG} and eventually saturates for large-enough V_{TG} values.

The 2D materials of the top and bottom 2D layers 106, 112 used in many of the examples herein are the hexagonal monolayer MoS₂ and WTe₂. The band structure for MoS₂ and WTe₂ may be determined using a density functional theory (DFT), which shows that these materials have a direct bandgap with the band edges for both the valence and the conduction band residing at the K point in the 2D Brillouin zone.

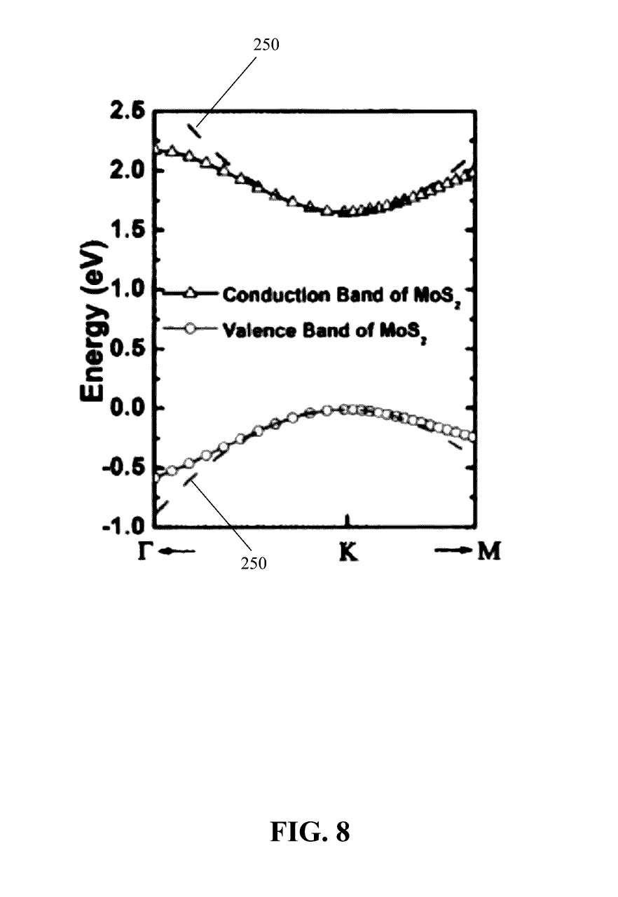

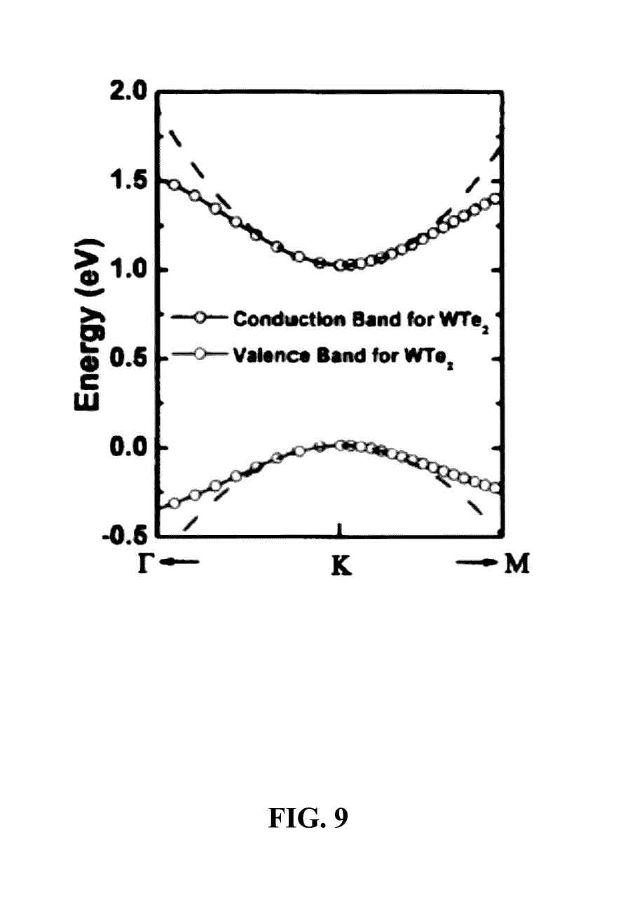

With respect now to FIGS. 8-9, FIG. 8 shows a band structure for a hexagonal monolayer MoS₂. FIG. 9 shows a band structure for hexagonal monolayer WTe₂ as obtained using the DFT method described in Gong et al., Applied Physics Letter, 103, 053513 (2013), which is incorporated herein by reference in its entirety. In general, FIGS. 8-9 show that in a range of about 0.4 eV from the band edges, the DFT results can be approximated fairly well by using an energy relation based on simple parabolic effective mass approximations 250, which are shown in dashed lines. Thus, the parabolic effective mass approximations 250 are adequate for the example Thin-TFET 100, which in many examples is geared towards extremely small supply voltages (e.g., <0.5 V). The values for the effective masses inferred from the DFT fitting are tabulated in Table 1 along with the band gaps and electron affinities for MoS₂ and WTe₂, which may be used to determine tunneling currents.

TABLE I

| | | Electron | Conduction band | Valence band |
|---|---|---|---|---|
| | Bandgap | affinity | effective mass | effective mass |
| | (eV) | (χ) | (mₒ) | (mₒ) |
| MoS₂ | 1.8 | 4.30 | 0.378 | 0.461 |
| WTe₂ | 0.9 | 3.65 | 0.235 | 0.319 |

In some examples, the top gate 102 of the example Thin-TFET comprises Aluminum, which has a work function of 4.17 eV. Likewise, in some examples, the back gate 108 of the example Thin-TFET comprises p++ Silicon, which has a work function of 5.17 eV. Further, in some examples, the top and bottom oxide layers 104, 110 have an effective oxide thickness (EOT) of 1 nm. In one example, the top 2D layer 106 comprises hexagonal monolayer MoS₂, while the bottom 2D layer 112 comprises hexagonal monolayer WTe₂. For purposes of discussion here, and at least in some examples, an n-type and p-type doping density of 10¹² cm⁻² by impurities and full ionization are present in, respectively, the top and bottom 2D layers 106, 112, and the relative dielectric constant of the interlayer 118 material is 4.2 (e.g., boron nitride). In one example, the voltage V_{DS} between the drain 114 and the source 116 is set to 0.3 V, and the back gate 108 is grounded unless stated otherwise. Further, the value of M_{B,0} can in some cases be determined from testing. In other cases, however, the value of M_{B,0} may be set to 0.01 eV, which is consistent with other applications, such as, for example, in a graphene/hBN system. For purposes of discussion herein, the value of M_{B,0} is set to 0.01 eV.

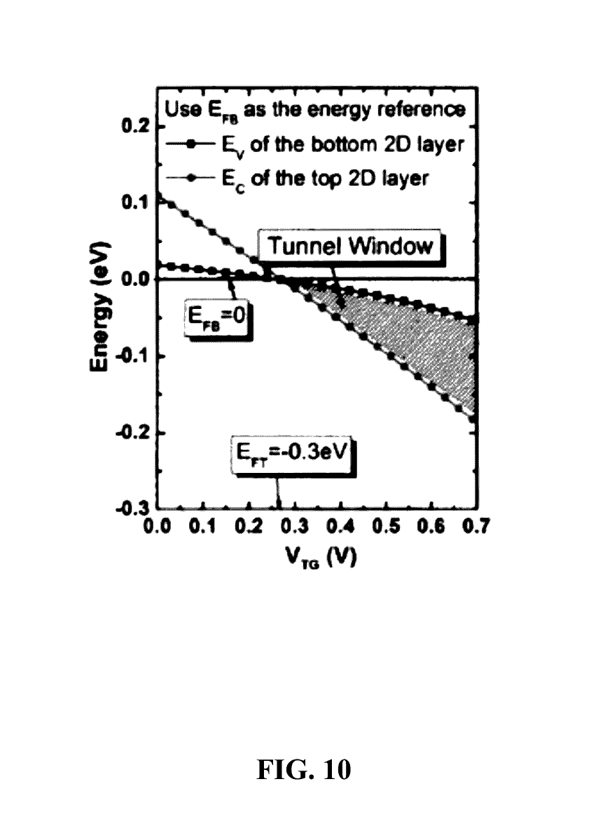

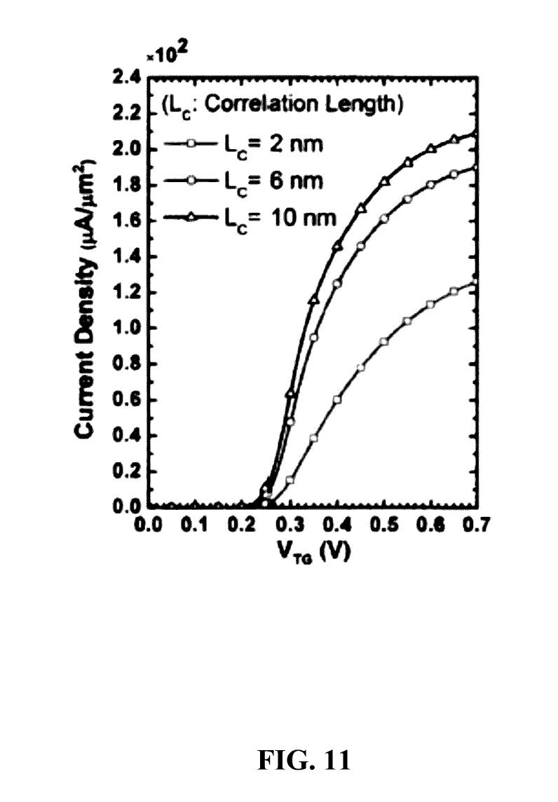

With respect to FIGS. 10-11, plots of band alignment and current density versus the top gate voltage V_{TG} are shown, where V_{BG}=0 and V_{DS}=0.3 V. In particular, FIG. 10 shows that the top gate voltage V_{TG} can effectively govern the band alignment in the example Thin-TFET 100 and, more particularly, the crossing and uncrossing between the conduction band minimum E_{CT} in the top 2D layer 106 and the valence band maximum E_{VB} in the bottom 2D layer 112, which discriminates between the ON and OFF states.

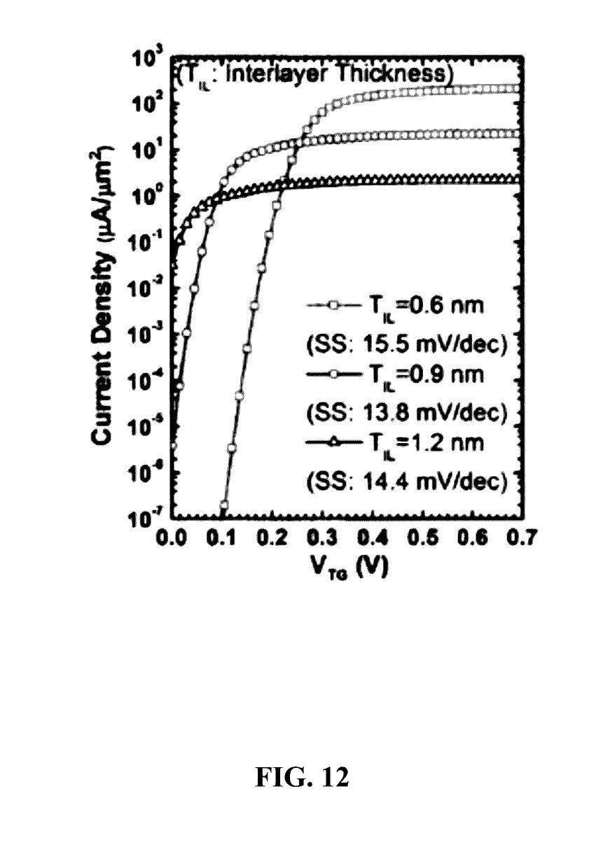

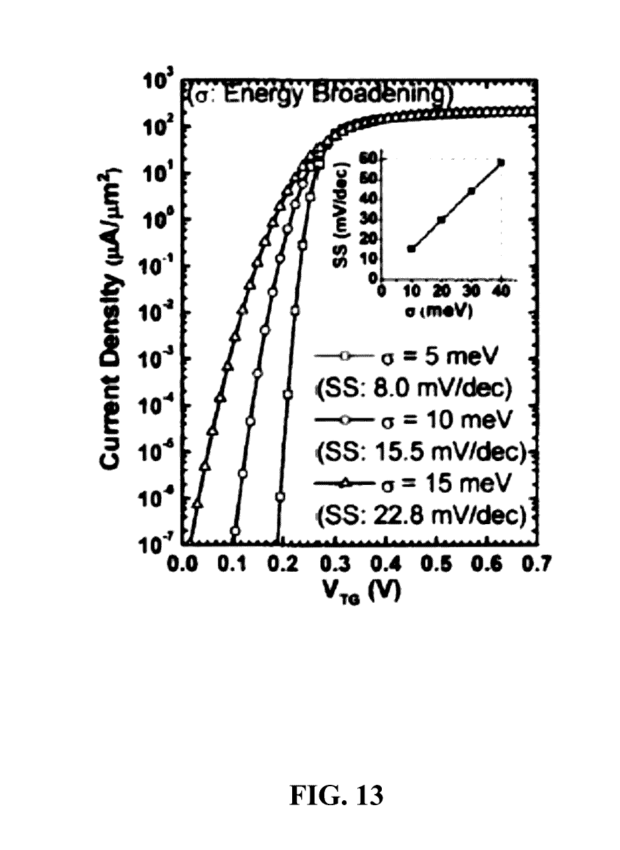

FIG. 11 plots tunnel current density I_{DS} versus the top gate voltage V_{TG} for different values of the correlation length L_{c}. In this example, the parameters used include a matrix element M_{BO} of 0.01 eV, a decay constant of wave-function in the interlayer 118 of κ=3.8 nm⁻¹, an energy broadening of σ=10 meV, and an interlayer thickness of T_{IL}=0.6 nm (e.g., roughly equivalent to the height of two atomic layers of BN). It should be understood that in some examples the interlayer thickness T_{IL} may be 0.3 nm or smaller. The tunnel current density I_{DS} versus V_{TG} characteristic plotted in FIG. 11 can be divided approximately into three different regions: a sub-threshold region, a linear region, and a saturation region. The sub-threshold region corresponds to the condition where E_{CT} is greater than E_{VB} (see also FIG. 10), although the very steep current dependence on V_{TG} is illustrated better in FIGS. 12-13 and is discussed below.

In the linear region of this example, the tunnel current density I_{DS} exhibits an approximately linear dependence on V_{TG} and, indeed, the current is roughly proportional to the energy tunneling window, as discussed above and represented in Equation (34). This follows because the tunneling window is small enough that the condition q_{M}²<<1/L_{c}², is fulfilled. In this linear region, the tunnel current density I_{DS} is proportional to the long-wavelength part of the scattering spectrum S_{F}(q) (i.e., small q values). Hence the current may increase with the correlation length L_{c}, as expected based on Equation (34). The super-linear behavior of the tunneling current density I_{DS} at small top gate voltage V_{TG} values observed in FIG. 11 may be due to the tail of the Fermi occupation function in the top 2D layer 106. When the top gate voltage V_{TG} increases above approximately 0.5 V, the tunneling current density I_{DS} in FIG. 11 enters the saturation region, where the tunneling current density I_{DS} increases as the top gate voltage V_{TG} slows down because of the decay of the scattering spectrum S_{F}(q) for q values larger than 1/L_{c}, as one having ordinary skill in the art would understand based on Equation (16).

FIGS. 12-13 show current-voltage (I-V) curves for different interlayer thicknesses T_{IL} and broadening energies σ. In FIGS. 12-13, the back gate voltage is taken to be zero, and the top gate voltage is taken to be 0.3 V. Also in these examples, an average inverse sub-threshold slope is extracted in the tunneling current density I_{DS} range from 10⁻⁵ to 10⁻² μA/μm². In FIG. 12, the energy broadening σ is taken to be 10 meV. That said, FIG. 12 shows that the tunneling current density I_{DS} increases exponentially as the interlayer thicknesses T_{IL} decreases. Further, the decay constant of κ=3.8 nm⁻¹ employed in these examples results in a dependence on interlayer thicknesses T_{IL} that is generally consistent with the dependence seen in graphene-based interlayer tunneling devices. Threshold voltages may also be lowered by increasing interlayer thickness T_{IL}. FIGS. 12-13 show that the T_{IL} impact on sub-threshold swing (SS) is relatively weak and that a very steep sub-threshold region is obtained for all of the interlayer thicknesses T_{IL} in FIG. 12. This follows because, in order for the example Thin-TFET 100 to obtain a small SS in some examples, it is necessary that the top gate voltage V_{TG} has tight control over the electrostatic potential in the top 2D layer 106, but has negligible or no influence on the potential of the bottom 2D layer 112. Thus, in some examples, the SS is insensitive to the interlayer thickness T_{IL} as long as the interlayer thickness T_{IL} does not change the control of the top gate voltage V_{TG} on such potentials. In other words, a larger interlayer thickness T_{IL} in many cases reduces substantially the tunneling current density I_{DS}, but does not deteriorate the SS.

FIG. 13 plots current density I_{DS} against top gate voltage V_{TG} for different values of energy broadening σ. The constants and variables utilized to obtain the results shown in FIG. 13 include M_{BO}=0.01 eV; a decay constant of wave-function in the interlayer 118 of κ=3.8 nm⁻¹; and an interlayer thickness of T_{IL}=0.6 nm (e.g., two atomic layers of BN).

FIG. 13 demonstrates that the SS is controlled in large part by the broadening energy σ of Equation (22). Such a result follows because in many examples the energy broadening σ is the physical factor that sets the minimum value for the SS, and the tunneling current density I_{DS} versus top gate voltage V_{TG} may approach a step-like curve when σ is zero due to the step-like DoS of the top and bottom 2D layers 106, 112. More specifically, FIG. 12 shows that the example Thin-TFET 100 provides an SS below the 60 mV/dec (i.e., the limit of conventional MOSFETs at room temperature), even for fairly large broadening energies up to about 40 meV.

It should be understood that energy broadening and band tails have already been recognized as a fundamental limit to the SS of band-to-band tunneling transistors, and are not a specific concern of the example Thin-TFET 100. Further, as already mentioned above, the band tails in three-dimensional (3D) semiconductors have been investigated by using thermal measurements and are described in terms of the so called Urbach parameter E₀. Values for the Urbach parameter E₀ comparable to room temperature thermal energy (i.e., k_{B}T≅26 meV) have been reported for GaAs and InP. By contrast, energy broadening and band tails in 2D materials play an important role in the minimum SS attainable by Thin-TFETs, and no data has been reported, synthesized, or utilized for band tails in monolayers of TMDs.

The example Thin-TFET 100 is a new steep slope transistor based on interlayer tunneling between two 2D semiconductor materials, namely, the top and bottom 2D layers 106, 112. The example Thin-TFET 100 allows for a very steep subthreshold region, and the SS may ultimately be limited by energy broadening in the two 2D materials comprising the top and bottom 2D layers 106, 112. The energy broadening can have different physical origins, such as, for example, disorder, charged impurities in the top and bottom 2D layers 106, 112 or in the surrounding materials, phonon scattering, and microscopic roughness at interfaces. Energy broadening has been accounted for here by assuming a Gaussian energy spectrum with no explicit reference to a specific physical mechanism. Moreover, while a possible rotational misalignment between the top and bottom 2D layers 106, 112 may affect the absolute value of the tunneling current, the misalignment does not significantly degrade the steep subthreshold slope offered by the example Thin-TFET 100, which may be the most crucial figure in terms of merit for a steep slope transistor.

Optimal operation of the example Thin-TFET 100 may require a good electrostatic control of the top gate voltage V_{TG} on the band alignments in the material stack, as shown for example in FIG. 10, which may become problematic if the electric field in the interlayer 118 is effectively screened by the high electron concentration in the top 2D layer 112. Consequently, because high carrier concentrations in the top and bottom 2D layers 106, 112 may be essential to reducing the layer resistivities, a tradeoff may exist between gate control and layer resistivities. Accordingly, doping concentrations in the top and bottom 2D layers 106, 112 may be important design parameters in addition to tuning the threshold voltage. In this respect, the science of chemical doping of TMD materials is progressing, and in-situ doping will likewise be very important for optimizing the example Thin-TFET 100.

Those having ordinary skill in the art will appreciate that the above description of the example Thin-TFET 100 does not explicitly account for possible traps or defects assisted tunneling, which are known to be a serious hindrance to tunnel-FETs exhibiting a SS better than 60 mV/dec. Further, from a fundamental viewpoint, 2D crystals may offer advantages over their 3D counterparts because they are inherently free of broken/dangling bonds at the interfaces.

In short, the example Thin-TFET 100 is based on interlayer tunneling between two 2D materials. The Thin-TFET 100 has a very steep turn-on characteristic because the vertical stack of 2D materials having an energy gap is allows for the most effective, gate-controlled crossing and uncrossing between the edges of the bands involved in the tunneling process.

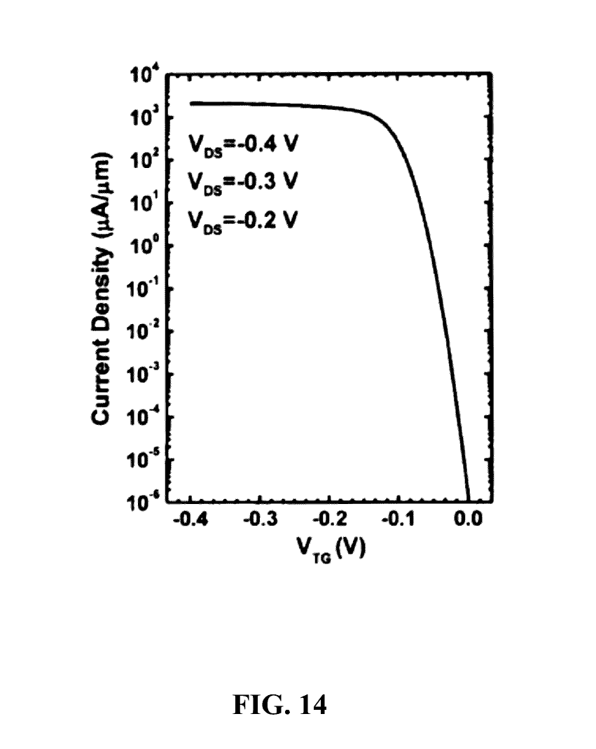

In view of the foregoing, various operating scenarios for the example Thin-TFET 100 were determined using an effective barrier height of the van der Waals gap between the top 2D layer 106 (in this example, SnSe₂) and the bottom 2D layer 112 (in this example, WSe₂) of 1.0 eV, a tunneling direction effective electron mass in van der Waals gap of m₀, a tunneling distance of 0.3 nm, a correlation length L_{c} of scattering of 10 nm, an R.M.S. value of the scattering potential (i.e., matrix element) of 0.05 eV, an energy broadening of the density-of-state of 10 meV, and a top and bottom oxide EOT of 1 nm. For the purposes of brevity and avoiding redundancy, the results of such operating scenarios shown in FIGS. 14-19 are not discussed in as much detail as set forth above as those having ordinary skill in the art will readily understand them.

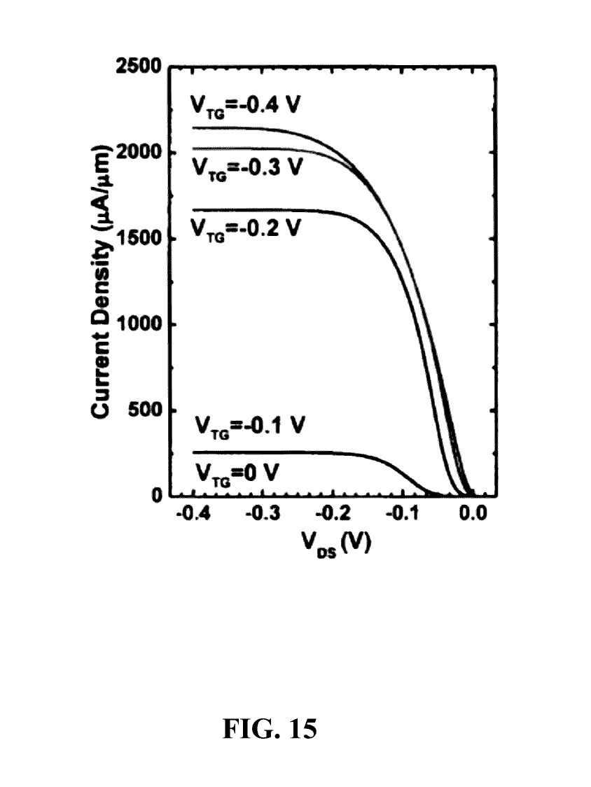

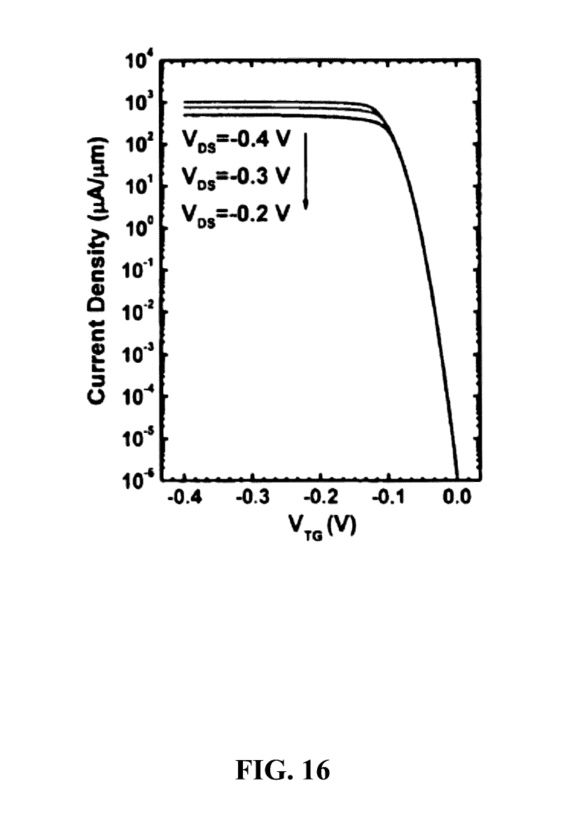

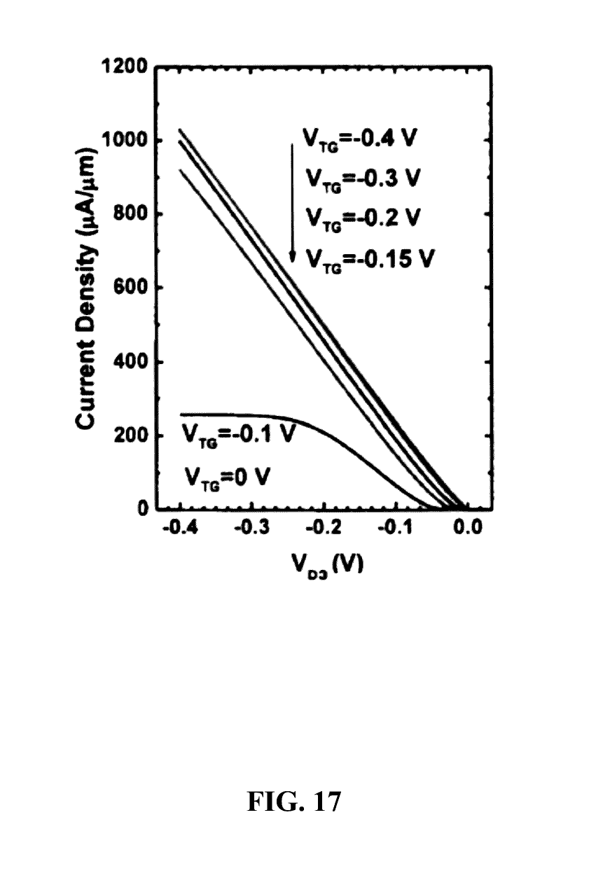

Based on these conditions and no contact resistance, FIG. 14 plots the tunneling current density I_{DS} versus top gate voltage V_{TG} for V_{DS} values of −0.4 V, −0.3 V, and −0.2 V. FIG. 15 plots the tunneling current density I_{DS} versus the drain-source voltage V_{DS} for a condition where no contact resistance is applied, but for various top gate voltages V_{TG} of −0.4 V, −0.3 V, −0.2 V, −0.1 V, and 0 V. In contrast, FIGS. 16-17 show tunneling current densities I_{DS} where a 160 Ωμm resistance per contact has been applied. In particular, FIG. 16 plots tunneling current density I_{DS} versus top gate voltage for various drain-source voltages V_{DS}. FIG. 17 plots tunneling current density I_{DS} versus drain-source voltage V_{DS} for various top gate voltages V_{TG}.

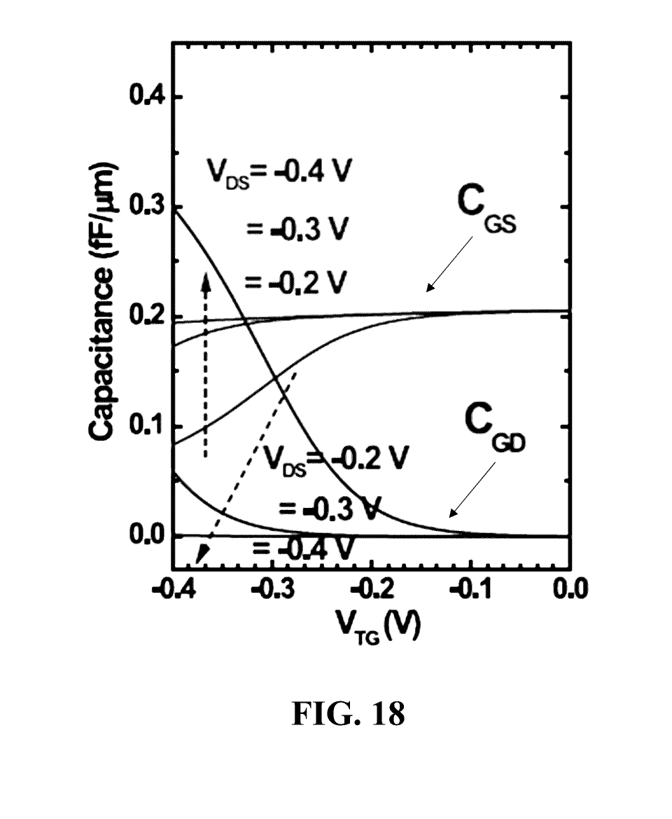

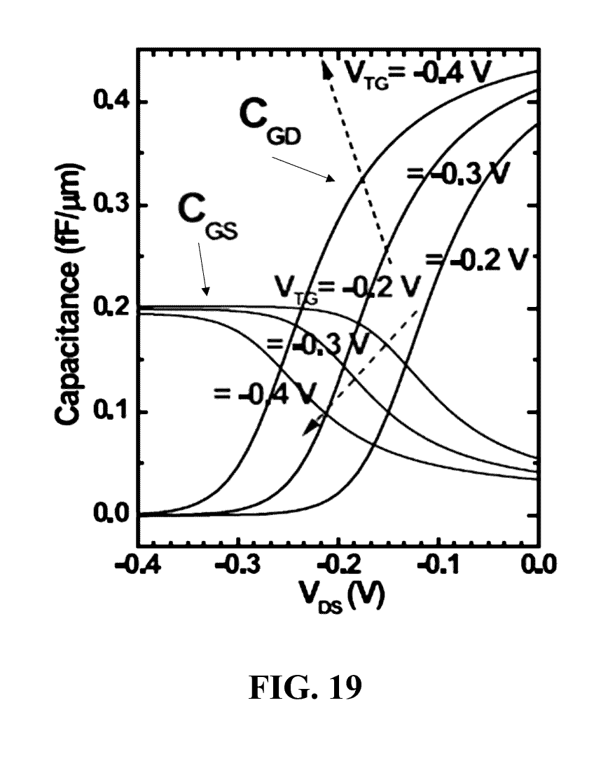

Based on the capacitance model 140 shown in FIG. 2, capacitance densities are plotted against top gate voltages V_{TG} and drain-source voltages V_{DS} in FIGS. 18-19. More specifically, FIG. 18 plots capacitance density as taken across terminals G-S and G-D of the capacitance model 140 versus top gate voltage V_{TG} for three different drain-source voltages V_{DS}, where no contact resistance is applied. FIG. 19 plots capacitance density as taken across terminals G-S and G-D of the capacitance model 140 versus drain-source voltage V_{DS} for various values of top gate voltage V_{TG}, where no contact resistance is applied.

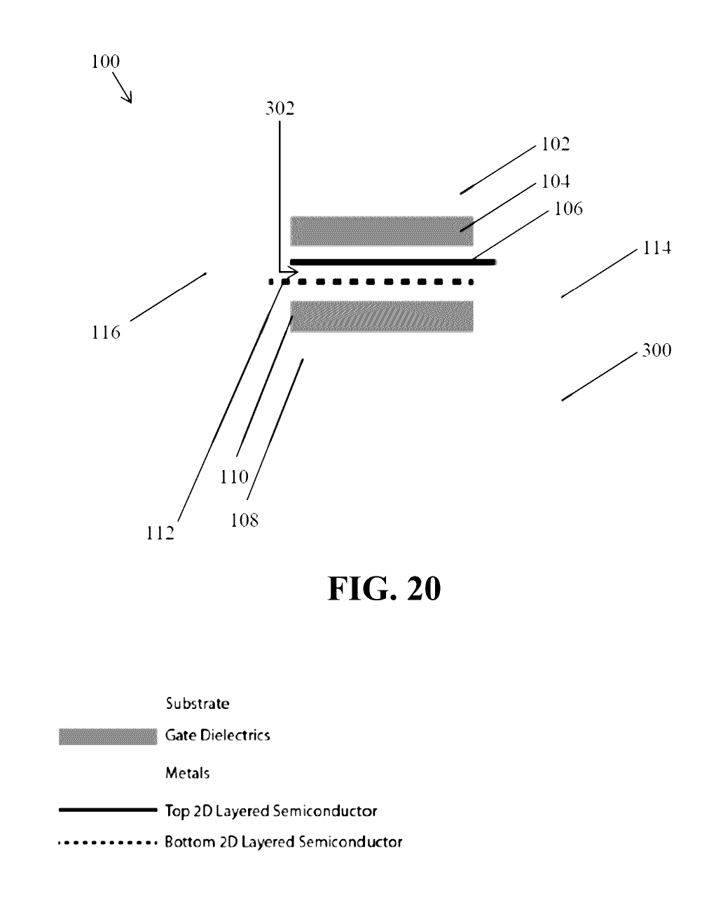

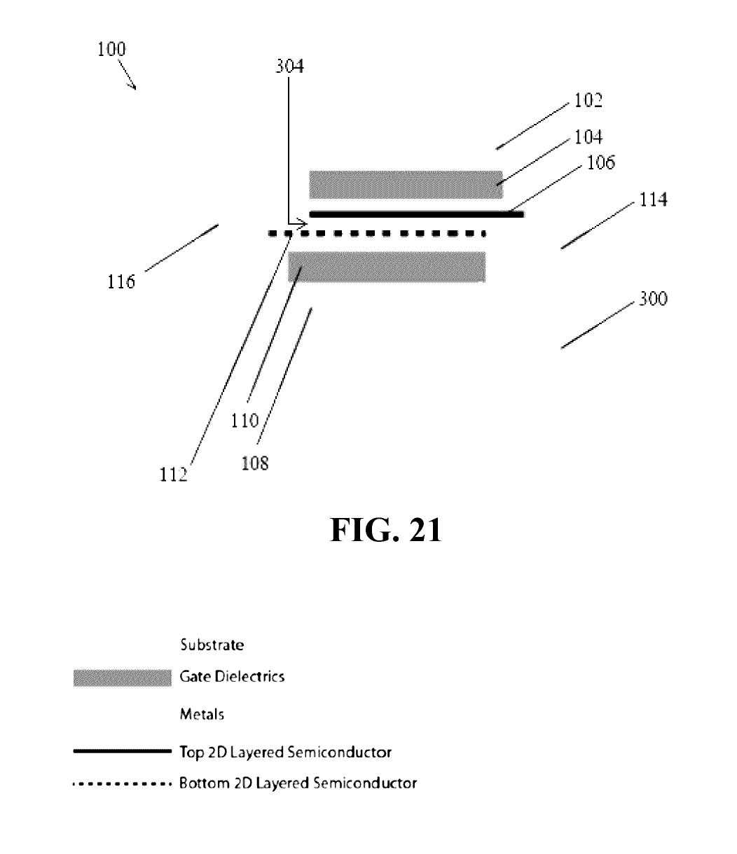

Still further, as shown in FIG. 20, the example Thin-TFET 100 may in some examples be positioned on a substrate 300 such that the top gate 102, the top oxide layer 104, the back oxide layer 110, the back gate 108, and an overlapping portion 302 of the top 2D layer 106 and the bottom 2D layer 112 are vertically aligned, or at least substantially vertically aligned. In other examples, however, certain components of the example Thin-TFET 100 may be intentionally misaligned. For instance, FIG. 21 illustrates the example Thin-TFET 100 wherein an overlapping portion 304 of the top 2D layer 106 and the bottom 2D layer 112 is smaller than the overlapping portion 302 shown in FIG. 20 because the top gate 102, the top oxide layer 104, and the top 2D layer 106 are laterally offset with respect to the bottom 2D layer 112, the back oxide layer 110, and the back gate 108.

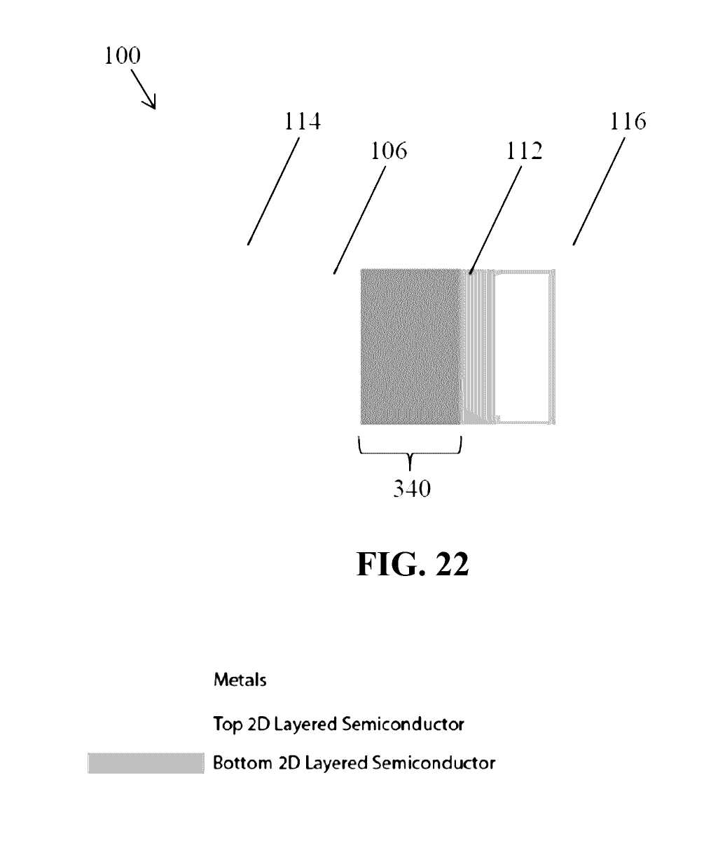

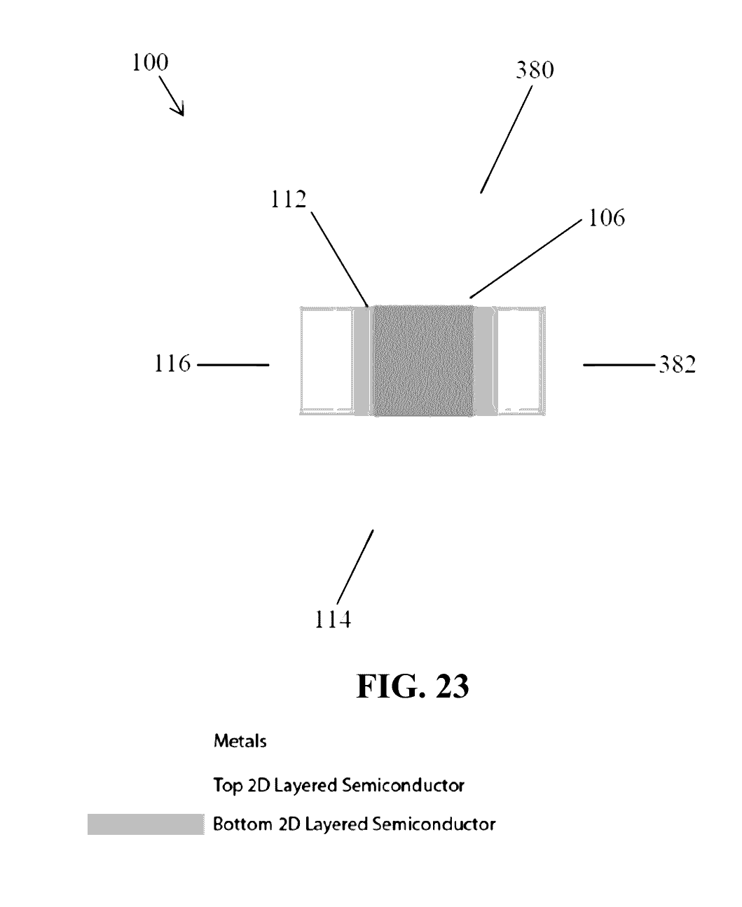

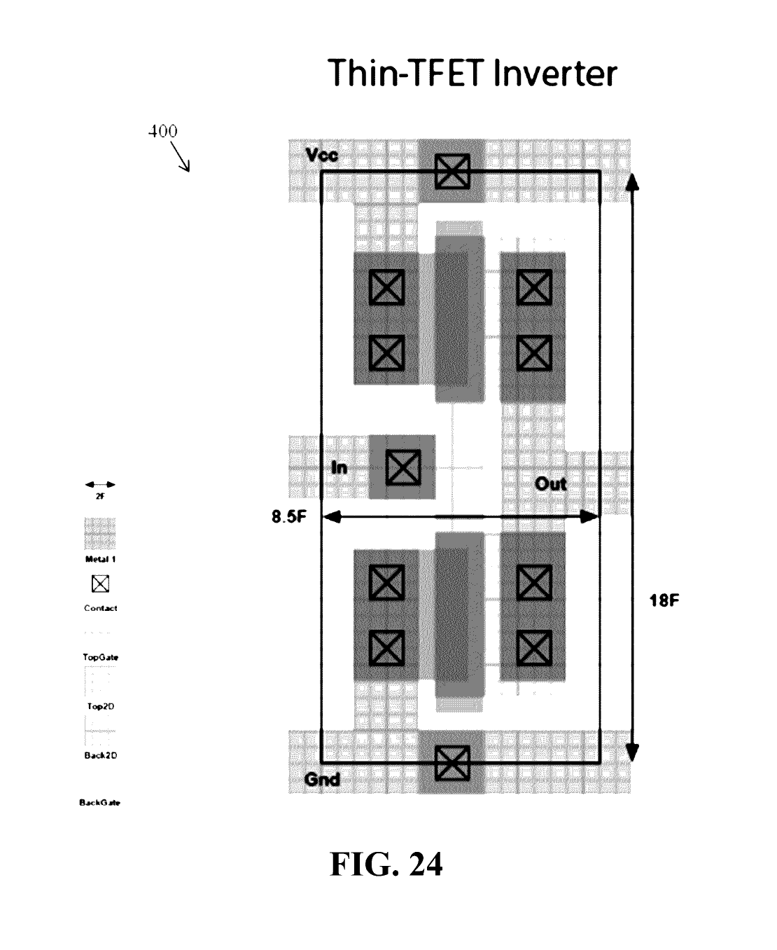

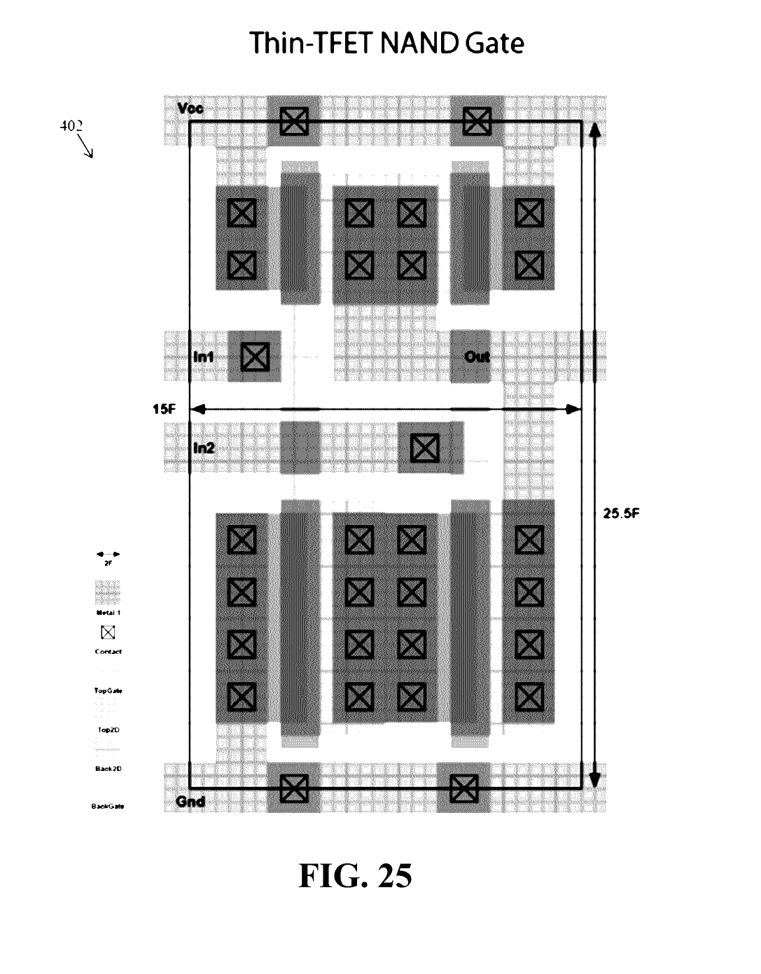

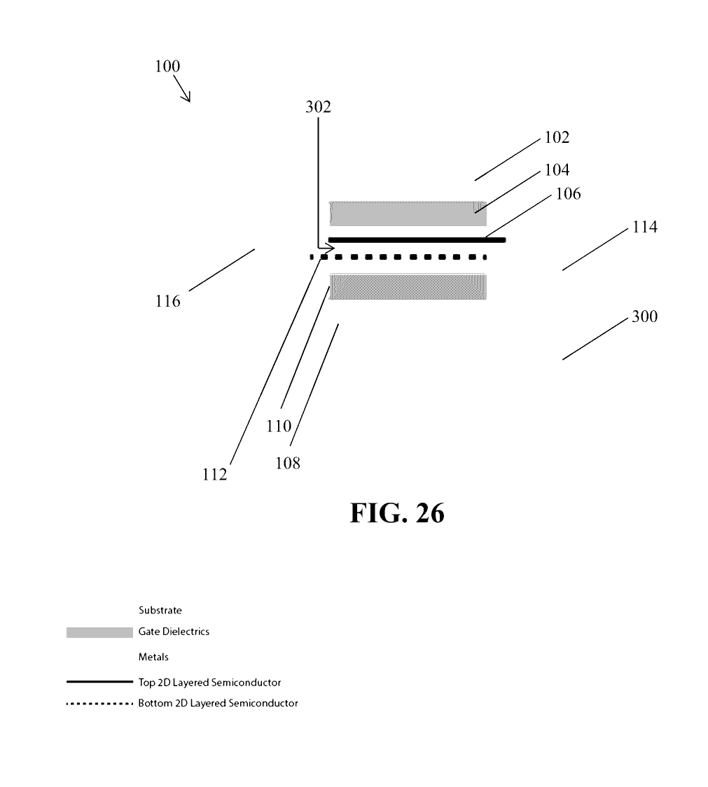

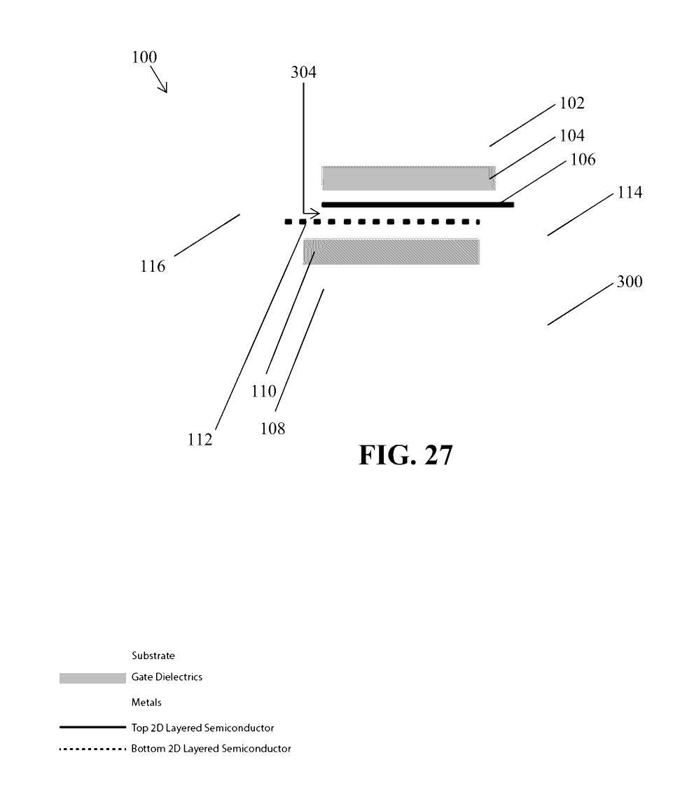

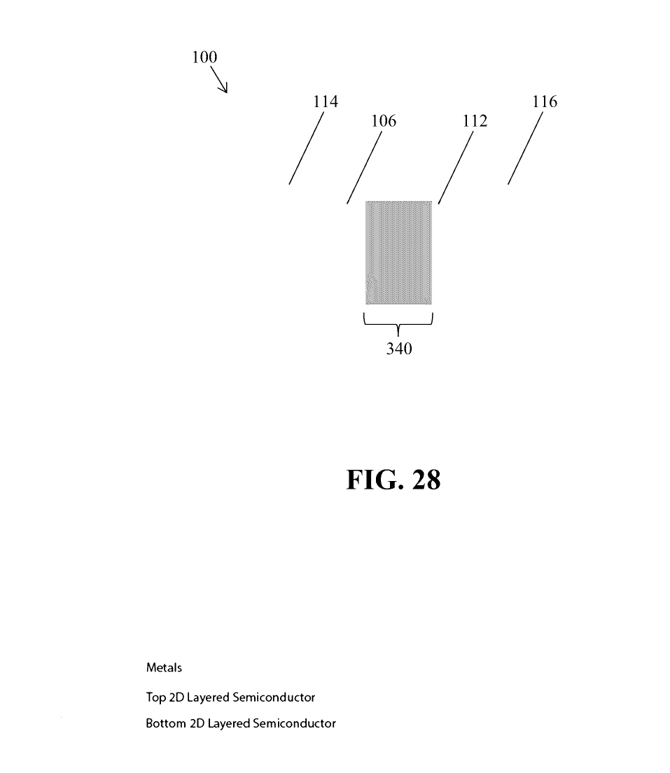

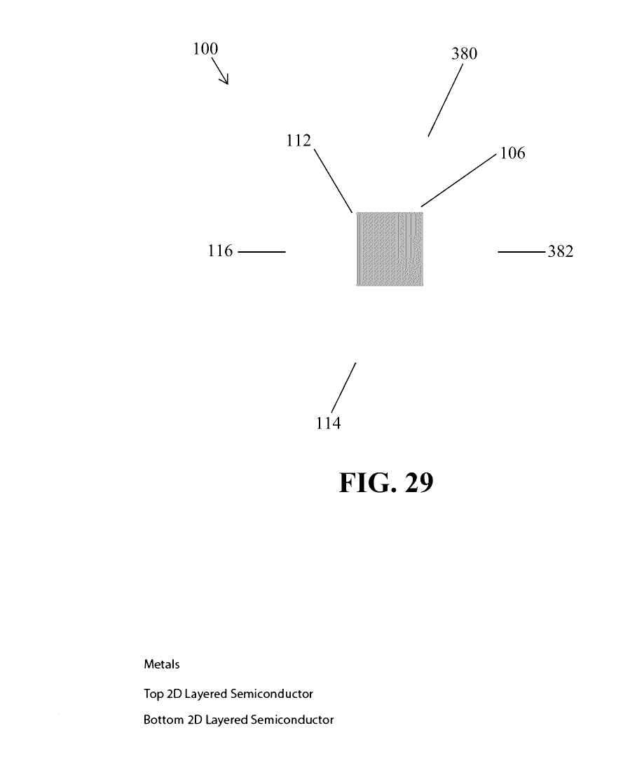

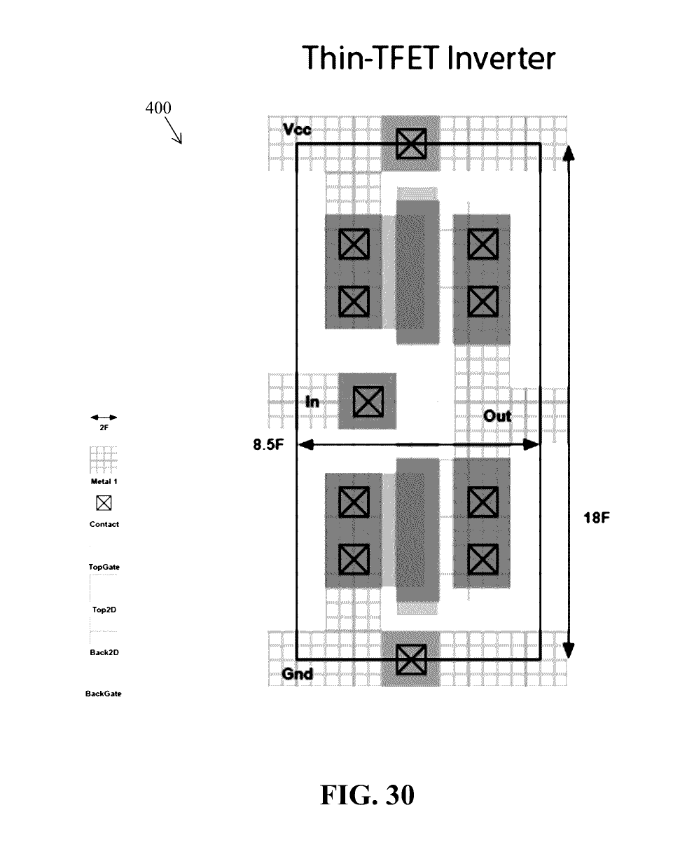

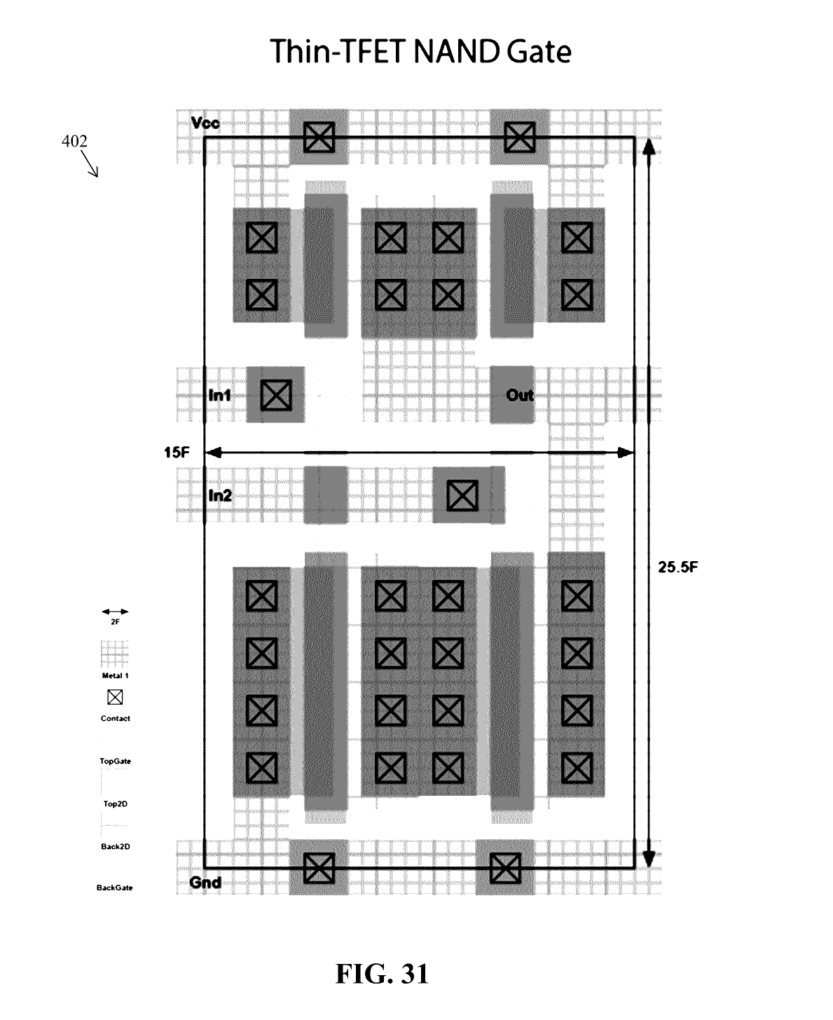

With reference now to FIG. 22, the example Thin-TFET 100 is shown from a top perspective. Moreover, the example Thin-TFET 100 is shown without a substrate, a top gate, or a bottom gate for purposes of clarity. In this example, one having ordinary skill in the art will appreciate how the top 2D layer 106, which is cantilevered from the source 116, and the bottom 2D layer 112, which is cantilevered from the drain 114, form an overlapping portion 340. In still another example, the top and bottom 2D layers 106, 112 may be arranged orthogonal to one another, as shown in FIG. 23. In the example of FIG. 23, the example Thin-TFET 100 includes a second drain 380 coupled to the top 2D layer as well as a second source 382 coupled to the bottom 2D layer 112. In still other examples, the top and bottom 2D layers 106, 112 may be arranged orthogonal to one another, but without a second source and a second drain such that the top and bottom 2D layers 106, 112 are cantilevered. As those having ordinary skill in the art will further understand, the example Thin-TFET disclosed herein may be employed in countless applications in which the Thin-TFET forms a part of a larger circuit. For instance, FIG. 24 shows how the example Thin-TFET may be utilized to form an inverter 400. FIG. 25, moreover, shows how the example Thin-TFET may be utilized to form a NAND gate 410.

The article by M. Li, et al., “Single particle transport in two-dimensional heterojunction interlayer tunneling field effect transistor,” J. of Applied Physics 115, 074508 (2014), is hereby incorporated by reference in its entirety. Further, although certain example methods and apparatus have been described herein, the scope of coverage of this patent is not limited thereto. On the contrary, this patent covers all methods, apparatus, and articles of manufacture fairly falling within the scope of the appended claims either literally or under the doctrine of equivalents.

1. A tunneling field effect transistor comprising:
a top gate;
a top oxide layer disposed at least partially beneath the top gate;
a top 2D layer disposed at least partially beneath the top oxide layer, the top 2D layer comprising a transition metal dichalcogenide;
a bottom 2D layer disposed at least partially beneath the top 2D layer, wherein the top and bottom 2D layers are separated by an interlayer, with the bottom 2D layer comprising a transition metal dichalcogenide;
a back oxide layer disposed at least partially beneath the bottom 2D layer;
a back gate disposed at least partially beneath the back oxide layer;
a drain coupled to the top 2D layer; and
a source coupled to the bottom 2D layer,
wherein the top and bottom 2D layers are devoid of a combination of a p+ crystal and an n+ crystal in the same layer,
wherein applying a voltage at at least one of the top gate or the back gate allows electrons to flow from the source to the drain and electrons flow via quantum tunneling from the conduction band of the bottom 2D layer to the valence band of the top 2D layer.

2. A tunneling field effect transistor of claim 1, wherein the top 2D layer comprises a different material than the bottom 2D layer.

3. A tunneling field effect transistor of claim 1, wherein the top and bottom 2D layers are comprised of monolayers of group-VIB transition metal dichalcogenides according to the formula MX₂, wherein M=molybdenum or tungsten, wherein X=sulfur, selenium, or tellurium.

4. A tunneling field effect transistor of claim 1, wherein the top 2D layer comprises SnSe₂ and the bottom 2D layer comprises WSe₂.

5. A tunneling field effect transistor of claim 1, wherein a lattice structure of the top 2D layer is rotationally misaligned relative to a lattice structure of the bottom 2D layer.

6. A tunneling field effect transistor of claim 1, wherein the top gate, the top oxide layer, the back oxide layer, the back gate, and an overlapping portion of the top and bottom 2D layers are vertically aligned.

7. A tunneling field effect transistor of claim 1, wherein the top gate, the top oxide layer, and the top 2D layer are laterally offset with respect to the bottom 2D layer, the back oxide layer, and the back gate.

8. A tunneling field effect transistor of claim 1, wherein tunneling of electrons from the bottom 2D layer to the top 2D layer occurs in a direction that is generally perpendicular to planes in which the top and bottom 2D layers reside.

9. A tunneling field effect transistor of claim 1, wherein an arrangement of the top and bottom 2D layers is formed by way of a dry transfer technique or by way of a chemical deposition technique.

10. A tunneling field effect transistor of claim 1, wherein the interlayer is formed at least in part by a van der Waals gap between the top and bottom 2D layers, wherein the tunneling field effect transistor is capable of achieving sub-threshold swing values below 60 mV/dec at room temperature.

11. A tunneling field effect transistor comprising:
a first gate, a first oxide layer, a first 2D layer, a second 2D layer, a second oxide layer, and a second gate arranged in a vertical configuration wherein the first and second 2D layers are separated by an interlayer and are comprised of monolayers of group-VIB transition metal dichalcogenides according to the formula MX₂, wherein M=molybdenum or tungsten, wherein X=sulfur, selenium, or tellurium, wherein the first and second 2D layers are devoid of a combination of a p+ crystal and an n+ crystal in the same layer, wherein the first 2D layer a different material than the second 2D layer;
a source coupled to the second 2D layer; and
a drain coupled to the first 2D layer,
wherein tunneling of electrons from the conduction band of the second 2D layer to the valence band of the first 2D layer occurs in a direction that is generally perpendicular to planes in which the first and second 2D layers reside.

12. A tunneling field effect transistor of claim 11 wherein the interlayer is less than 1 nanometer.

13. A tunneling field effect transistor of claim 12, wherein the interlayer is formed at least in part by a van der Waals gap between the first and second 2D layers.

14. A tunneling field effect transistor of claim 11, wherein a lattice structure of the first 2D layer is rotationally misaligned relative to a lattice structure of the second 2D layer.

15. A tunneling field effect transistor of claim 11, wherein an arrangement of the first and second 2D layers is formed by way of a dry transfer technique or by way of a chemical deposition technique.

16. A tunneling field effect transistor of claim 11, wherein the first and second 2D layers are oriented in a crisscross arrangement.

17. A tunneling field effect transistor comprising:
a first oxide layer;
a first 2D layer disposed at least partially adjacent the first oxide layer, the first 2D layer comprising a transition metal dichalcogenide;
a second 2D layer disposed at least partially adjacent the first 2D layer, with the second 2D layer comprising a transition metal dichalcogenide;
a second oxide layer disposed at least partially adjacent the second 2D layer;
a drain operably coupled to the first 2D layer; and
a source operably coupled to the second 2D layer,
wherein the first and second 2D layers are separated by an interlayer formed at least in part by a van der Waals gap and wherein electrons flow via quantum tunneling from the conduction band of second 2D layer to the valence band of the first 2D layer.

18. A tunneling field effect transistor of claim 17, wherein the first and second 2D layers are devoid of a combination of a p+ crystal and an n+ crystal in the same layer.

19. A tunneling field effect transistor of claim 18, wherein the first and second 2D layers are comprised of monolayers of group-VIB transition metal dichalcogenides according to the formula MX₂, wherein M=molybdenum or tungsten, wherein X=sulfur, selenium, or tellurium, wherein the first and second 2D layers are comprised of different materials.

20. A tunneling field effect transistor of claim 18, wherein either the first and second 2D layers are either rotationally misaligned or laterally offset.
